(19) United States
(12) Patent Application Publication
(10) Pub. No.: US 2026/0361049 A1
(43) Pub. Date: Nov. 12, 2026

(54) SHORT CAVITY ELECTRO-ABSORPTION MODULATED LASER

(71) Applicant: Mellanox Technologies, Ltd., Yokneam (IL)

(72) Inventors: Uziel KOREN, Haifa (IL); Yuri BERK, Kiryat Tivon (IL); Oren STEINBERG, Tal Shahar (IL); Moshe ORON, Haifa (IL); Guy SERI, Haifa (IL); Isabelle CESTIER, Haifa (IL); Elad MENTOVICH, Tel Aviv (IL)

(21) Appl. No.: 19/200,849

(22) Filed: May 7, 2025

(51) Int. Cl. H01S 5/026; H01S 5/0234; H01S 5/024; H01S 5/10; H01S 5/125

(52) U.S. Cl. CPC H01S 5/0265; H01S 5/0234; H01S 5/02453; H01S 5/125; H01S 5/1014

(57) ABSTRACT

According to certain embodiments, an electro-absorption modulated laser (EML) is provided. The EML includes a short optical gain section comprising a gain section number of quantum well layers; and an absorption section comprising an absorption section number of quantum well layers. The absorption section number of quantum well layers is larger than the gain section number of quantum well layers. The laser cavity including the optical gain section is defined by a first Bragg grating disposed between the optical gain section and the absorption section.

### BACKGROUND

As artificial intelligence and/or machine learning use increases, the amount of information being communicated between large clusters of computing resources (e.g., graphical processing units (GPUs), central processing units (CPUs), data processing units (DPUs), and/or the like) is also increasing. The amount of power consumption needed to transmit all this data is increasing exponentially. Accordingly, a need exists for high bandwidth power efficient optical sources for use in datacenter applications.

### GENERAL DESCRIPTION

Datacenters rely on a fast and robust communication infrastructure. This is achieved by using optical interconnects. As data processing requests of datacenters continues to increase, so does the desired bit rate for optical interconnects used to communicate between various components of a datacenter. Each physical link employing a single optical fiber may include multiple communication channels, which are distinguished by different wavelengths in wavelength division multiplexing (WDM) systems, however, most short reach optical links (such as VCSEL based links) are using a single wavelength per fiber. Such optical interconnects tend to include transceivers that are in optical communication with one another via one or more optical fibers. A transceiver includes one or more optical signal generating components and/or one or more optical signal detecting components. For example, a transceiver may include one or more semiconductor devices (e.g., vertical cavity surface emitting lasers (VCSELs); distributed-feedback (DFB) lasers; comb lasers; light emitting diodes (LEDs); modulators such as electro-absorption modulators, intensity and/or phase modulators, and other modulators; electro-absorption modulated lasers (EML); and/or the like) configured to generate optical signals and/or one or more semiconductor devices (e.g., photodiodes) configured for detecting optical signals.

The transmitters in optical short reach transceiver modules are often based on discrete single wavelength lasers, such VCSELs. The VCSELs may then be directly modulated to generate optical signals having digital data streams encoded thereon. Forthcoming optical links require optical transmitters capable of operating with high bandwidth (BW) in the range of 30-120 GHz and beyond. Conventional short reach sources, such as VCSELs, are not currently capable of meeting these high bandwidth requirements and are typically limited to less than 35 GHz. Additionally, it is desired for short reach sources to have reduced electrical power consumption compared to conventional long reach sources. For example, it is desired to have lasers with small threshold currents and high quantum efficiency It is also desirable to have electro-absorption modulators (EAMs) that require low power consumption from their RF drivers. The present disclosure provides technical solutions to these technical problems by providing high bandwidth electro-absorption modulated laser (EML)-based optical links that have reduced the power consumption.

As transceivers increase their line bitrate, currently from 25 Gbit/s to 50 Gbit/s and then to 100 Gbit/s, as well as upgrade the modulation order from present techniques like non-return-to-zero (NRZ) to pulse amplitude modulation level 4 (PAM-4), low electrical power consumption is important. The electrical power consumption of the transmitter is composed of several elements such as the DC power consumption of the laser, the power consumption of the RF driver and that of the electronic digital signal processing (DSP). It is therefore necessary to optimize the optical source to reduce the sum of power consumption for all these elements.

This is particularly relevant for transceivers that need to be encapsulated in standardized pluggable forms, which have limited heat dissipation properties and small space, such that they rely on air flow design, thereby limiting the amount of power transceivers can take from the main rack by the form-factor standards.

Various embodiments provide short cavity electro-absorption modulated semiconductor lasers (EMLs). In various embodiments, an EML includes an optical gain section comprising a gain section number of quantum well layers and an absorption section comprising an absorption section number of quantum well layers. The absorption section number of quantum well layers is larger than the gain section number of quantum well layers. For example, in certain embodiments, the optical gain section includes two to five quantum well layers and the absorption section includes ten to twenty quantum well layers. In various embodiments, a laser cavity comprising the optical gain section is defined by at least one Bragg grating disposed between the optical gain section and the absorption section. By defining the laser cavity, at least in part, by the Bragg grating, an electrically efficient laser cavity is provided. Moreover, due to the larger absorption section number of quantum well layers, compared to the gain section number of quantum well layers, for example, the EML is configured to efficiently modulate the continuous wave (CW) laser beam emitted from the laser cavity (e.g., via the Bragg grating). Thus, various embodiments, provide EMLs with improved performance.

Moreover, EMLs of various embodiments are configured for use as optical sources, such as wavelength division multiplexing (WDM) sources, of optical interconnects. An array of EMLS of various embodiments, where each EML is configured to emit a laser beam of a different wavelength may be used to provide short reach sources or WDM sources. For example, such an array of EMLs may provide an affordable, power efficient, high BW, high power WDM source with a desired optical wavelength spacing. Dense low-power interfaces are paramount to continue scaling AI/ML systems to interconnect large clusters (GPUs, CPUs, DPUs, . . . ). Compared to a multiple externally modulated VCSEL implementation, various embodiments provide optical sources with high bandwidth and with scalability for future generations bit rates.

In certain applications, an EML may be coupled to an output waveguide (e.g., directly, evanescently, and/or the like). The output waveguide may be used to optically couple the EML to an optical fiber or to a multiplexer, a photonic integrated circuit (PIC), and/or the like.

The EML comprises a semiconductor laser that is monolithically integrated with a modulator. The output waveguide of the EML is configured to provide a modulated laser beam to an optical fiber or to a multiplexer, PIC, and/or the like. For example, the EML may be part of an interconnect used for optical communications for short to medium distance (e.g., up to 2 km).

In various embodiments, one or more of the EMLs may be incorporated into a transceiver of an optical interconnect or optical link within large networks. For example, EMLs of various embodiments may be used as the optical source(s) of a transmitter module of a transceiver.

In at least one example embodiment, the optical interconnect is part of a datacenter that corresponds to a collection of network devices, such as network switches (e.g., Ethernet switches, IP routers, multiservice platforms, various transmission network elements, legacy communication equipment, or in any other suitable communication system) connected with a collection of servers or compute nodes. A switch fabric serves to transfer the data between the switch ports. A switch fabric comprises one or more interconnect circuits, which may be arranged in various switch fabric architectures, e.g., m*m crossbar, Banyan, Benes, Omega, Clos, multi-plane, STS, TST, shared memory, buffered crossbar, any other suitable blocking or non-blocking architecture, or any applicable mixed architecture thereof. A switch fabric is realized in typical embodiments by hardware, which may comprise Field-Programmable Gate Arrays (FPGAs) and/or Application-Specific Integrated Circuits (ASICs), and in some implementations also bus interconnects. The datacenter may adhere to a networking topology (e.g., a hierarchal networking topology), such as a fat tree topology, a Slim Fly topology, a Dragonfly topology, and/or the like. The datacenter routes traffic amongst the network switches and servers therein, and at least one layer of the topology in the datacenter is coupled to the communication network to allow networking traffic to flow between the datacenter and the network device(s).

The optical interconnect may include a substrate and an electro-optical component (one or more semiconductor lasers, one or more photodiodes, etc.) supported by the substrate and configured to convert electrical signals to optical signals or vice versa. The optical interconnect may further include a transmission block defining a receiving surface configured to receive an optical fiber, and a waveguide configured to transmit optical signals between the electro-optical component and the receiving surface such that in an operational configuration in which the receiving surface receives an optical fiber, the electro-optical component and the optical fiber are in optical communication.

While the present disclosure illustrates and describes the optical interconnect without a housing or other protective casing, as would be understood by one of ordinary skill in the art in light of the present disclosure, some or all of the optical interconnect may be supported or enclosed by any housing used in communications systems to protect the components supported therein (e.g., as part of Quad Small Form-factor Pluggable (QSFP) connectors, Small Form Pluggable (SFP) connectors, or the like). Furthermore, the substrate hosting the electro-optical component may be substantially rectangular shape and/or may be dimensioned (e.g., sized and shaped) for use in any communication system regardless of geometric constraints (e.g., L-shaped, squared-shaped, etc.).

In various embodiments, an optical interconnect for receiving an optical fiber may be implemented in a flip-chip configuration. In certain embodiments, the optical interconnect is configured as a flip-chip component such that a longitudinal axis of the first adiabatic transition profile of the optical interconnect and a longitudinal axis of the second adiabatic transition profile of the optical interconnect may be collinear. Said differently, the orientation of the optical interconnect in such an embodiment does not require a mirror or other reflective surface to redirect optical signals between the electro-optical component and the receiving surface. As would be evident to one of ordinary skill in the art in light of the present disclosure, however, the optical interconnect in a flip-chip configuration may also include one or more mirrors (e.g., reflective surfaces) to accommodate optical fibers received at varying angles. In some optical interconnect embodiments, only mirrors may be operationally configured to redirect light given that at some bending radii, light may remain confined to the waveguide. Accordingly, embodiments of a field replaceable modular optical interconnect unit are described that are configured to be received by a main switch system box. The field replaceable modular optical interconnect unit comprises a housing comprising at least a front panel, a rear panel, and side panels extending between the front and rear panels, a printed circuit board assembly supported within the housing, an optical module supported on the printed circuit board assembly and configured to convert between optical signals and corresponding electrical signals for respectively transmitting or receiving optical signals through a fiber optic cable, a board-to-board connector disposed on the rear panel of the housing and configured to enable electrical signals to be transmitted between the printed circuit board assembly and a main switch system box, and an external connector disposed on the front panel of the housing and configured to engage an external optical fiber for transmitting optical signals between the optical module and an external component. The field replaceable modular optical interconnect unit may be configured to be electrically connected to the main switch system box via engagement of the board-to-board connector with a corresponding connector of the main switch system box when the housing is received by the main switch system box.

In some embodiments, the optical module may be a mid-board optical module (MBOM), and/or the field replaceable modular optical interconnect unit may comprise a plurality of external connectors. For example, the external connector may be a first external connector, and the field replaceable modular optical interconnect unit may further comprise a second external connector disposed on the front panel of the housing and configured to enable transmission of electrical signals between the printed circuit board assembly and an external component connected thereto.

In some embodiments, the disclosed technique provides an electro-optical (EO) interconnect assembly comprising a pair of pluggable EO transceivers connected at respective ends of an optical fiber. The EO transceivers are typically used to connect network-connected devices (e.g., remote client switches, network adapters such as Network Interface controllers (NICs) and Host Channel Adapters (HCAs), Smart-NICs (NICs having embedded CPUs), network-enabled Graphics Processing Units (GPUs), and the like). The terms “network-connected device” and “network device” are used interchangeably herein. In certain embodiments, an optical interconnect includes a substrate, one or more optical waveguides, one or more first micro-lenses, one or more second micro-lenses, and first and second mechanical fixtures.

Various embodiments relate to interconnects (e.g., interconnect topologies) that are scalable and advantageous for networks that require a large number of all-to-all or point-to-point links between one or more node or send/receive pairs. In particular, silicon photonics interconnects or topologies are provided herein that may achieve at least moderate bandwidth between many nodes with physical, optical fiber connections. In some implementations, the one or more node or send/receive pairs are coupled with an optical fiber allowing a single wavelength to pass therebetween. In other implementations, multiple wavelengths or groups of wavelengths may be transmitted or received by nodes while simultaneously passing multiple wavelengths or groups of wavelengths to other nodes via optical fiber loops connecting three or more nodes. In some implementations, such interconnects as described herein do not rely on or include one or more of the following: wavelength synchronization between transmit and receive pairs, arbitration of the fiber(s), demultiplexers on the receiver side, and/or an optical crossbar. In some implementations, the optical interconnects may be sized to fit a face-plate form factor or as a mid-board optical connector or co-packaged optics. In some embodiments, the present disclosure provides optical interconnects for high bandwidth density applications like switches and GPUs or other processing elements. In one example, the processing elements may include central processing units (CPUs), graphics processing units (GPUs), data processing units (DPUs), quantum processing units (QPUs), a plurality of parallel processing units (PPUs), and application-specific integrated circuits (ASICs). QPUs are configured to perform one or more operations associated with a quantum algorithm. In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU that the local qubits are associated with.

A “node” as described herein may refer to a network switch to which a plurality of computer processing units (CPUs), graphical processing units (GPUs), data processing units (DPUs), or memory media are connected in an arbitrary number. The network switch may communicate with other network switches of the same kind to which the same processor and memory units may be connected. However, in other implementations, “node” may also refer to a processor which may be responsible for communication with all other nodes in the network or subnetwork.

An “optical fiber” as described herein can refer to a single optical fiber (e.g., including a core and a cladding) to provide unidirectional optical communication, can refer to a bidirectional pair of optical fibers (e.g., each including a core and a cladding) to provide both transmit and receive communications in an optical network, or can refer to a multi-core fiber, such that a single cladding could encapsulate a plurality of single-mode or multi-mode cores. Optical fibers can extend contiguously and uninterrupted between node or send/receive pairs (e.g., via pass-through connections) or include two or more fibers connected via fiber-to-fiber connections such that the fibers function or perform as a single fiber.

Silicon Photonics (SiP) is a technology that enables optical systems to be manufactured using silicon processes with silicon as the optical medium. Various optical components, such as interconnects and signal processing components, may be fabricated and integrated in a single SiP device. Some SiP devices are fabricated on a silica substrate or over a silica layer on a silicon substrate, a technology that is often referred to as Silicon on Insulator (SOI). In certain optical systems, a SiP device is attached to an external device to facilitate optical communications. However, it is generally difficult to accurately align light signals on the SiP with an external device that receives the light.

In certain optical systems, a SiP device is attached to an external device to facilitate optical communications. For example, the system includes one or more waveguides that carry light signals to and/or from optical chips. Examples of optical chips that can be included on the device include, but are not limited to, one or more components selected from a group consisting of facets through which light signals can enter and/or exit a waveguide, entry/exit ports through which light signals can enter and/or exit a waveguide from above or below the device, multiplexers for combining multiple light signals onto a single waveguide, demultiplexers for separating multiple light signals such that different light signals are received on different waveguides, optical couplers, optical switches, lasers that act as a source of a light signal, amplifiers for amplifying the intensity of a light signal, attenuators for attenuating the intensity of a light signal, modulators for modulating a signal onto a light signal, modulators that convert a light signal to an electrical signal, and vias that provide an optical pathway for a light signal traveling through the device. Additionally, the device can optionally, include electrical components. For instance, the device can include electrical connections for applying a potential or current to a waveguide, controlling active optical components, such as modulators, for example, and/or for controlling other components on the optical device.

According to a first aspect of the present disclosure, an EML is provided. In an example embodiment, the EML is a short cavity, GaAs-based EML. In an example embodiment, the EML includes an optical gain section comprising a gain section number of quantum well layers; and an absorption section comprising an absorption section number of quantum well layers. The absorption section number of quantum well layers is larger than the gain section number of quantum well layers. A laser cavity comprising the optical gain section is defined, in part, by a first Bragg grating disposed between the optical gain section and the absorption section. A waveguide Bragg grating is a series of consecutive regions with a periodical change in the effective refractive index of the waveguide. A Bragg grating has a specific spectral wavelength range where it is optically reflective which is called the stop band (SB) of the grating.

In an example embodiment, the gain section is shorter than 100 um, and the Bragg grating located between the optical gain section and the absorption section has a peak reflectivity of at least 35%.

In an example embodiment, the EML further includes a second Bragg grating disposed longitudinally on an opposite side of the optical gain section, wherein the first Bragg grating and the second Bragg grating longitudinally define the laser cavity.

In an example embodiment, the first Bragg grating defines a first stop band, and the second Bragg grating defines a second stop band, and the first stop band and the second stop band are offset from one another by a fraction of respective widths of the first stop band and the second stop band.

In an example embodiment, an overlap in the first stop band and the second stop band defines a wavelength overlap region and a width of the wavelength overlap region is smaller than the respective widths of the first stop band and the second stop band and the width of the wavelength overlap region is smaller or comparable to a mode spacing of the laser cavity, to cause the EML laser to operate in a single longitudinal optical mode.

In an example embodiment, the EML further includes at least one of (a) a gain section distributed feedback Bragg grating disposed within the optical gain section and having a smaller coupling coefficient than the first Bragg grating, or (b) one or more laterally coupled distributed feedback Bragg gratings that are each disposed laterally on one or more sides of the optical gain section and are each optically coupled to an optical mode propagating in the optical gain section.

In an example embodiment, the at least one of the gain section distributed feedback Bragg grating or the one or more laterally coupled distributed feedback Bragg gratings comprise a ¼ wavelength phase shift configured to cause the laser to operate in a single longitudinal mode.

In an example embodiment, the EML further includes a mirror, wherein the laser cavity is longitudinally defined by the mirror and the first Bragg grating, the mirror being disposed on a longitudinally opposite end of the optical gain section with respect to the first Bragg grating, and the mirror is a cleaved mirror with a high reflectivity coating.

In an example embodiment, the EML further includes at least one of (a) a gain section distributed feedback Bragg grating disposed within the optical gain section and having a smaller coupling coefficient than the first Bragg grating, or (b) one or more laterally coupled distributed feedback Bragg gratings that are each disposed laterally on one or more sides of the optical gain section and are each optically coupled to an optical mode propagating in the optical gain section.

In an example embodiment, the at least one of the gain section distributed feedback Bragg grating or the one or more laterally coupled distributed feedback Bragg gratings comprise a ¼ wavelength phase shift configured to cause the laser to operate in a single longitudinal mode.

In an example embodiment, the at least one of the gain section distributed feedback Bragg grating or the one or more laterally coupled distributed feedback Bragg gratings defines a feedback stop band, the first Bragg grating defines a first stop band and the first stop band and the feedback stop band are offset from one another by a fraction of respective widths of the first stop band and the feedback stop band, an overlap in the first stop band and the feedback stop band defines a wavelength overlap region and a width of the wavelength overlap region is smaller than the respective widths of the first stop band and the feedback stop band and the width of the wavelength overlap region is smaller or comparable to a mode spacing of the laser cavity, to cause the EML laser to operate in a single longitudinal optical mode.

In an example embodiment, the absorption section is longitudinally divided into several absorption segments separated by a passive optical waveguide segments to form a travelling wave electro-absorption modulator.

In an example embodiment, the travelling wave electro-absorption modulator is configured to be driven by a differential electrical RF signal.

In an example embodiment, the EML further includes an integrated resistive heater disposed proximate the absorption section, wherein the integrated resistive heater is in thermal communication with the quantum well layers of the absorption section.

In an example embodiment, the integrated resistive heater is operable to maintain the quantum well layers of the absorption section at a substantially constant temperature corresponding to an operating temperature value when an ambient temperature of an environment about the EML falls below the operating temperature value.

In an example embodiment, the EML is formed on a chip and the chip is configured to be flip-chip bonded to a silicon photonic chip via laser bonding pads, modulator bonding pads, and heater bonding pads of the silicon photonic chip and laser pads, modulator pads, and heater pads of the chip on which EML is formed, wherein the laser pads and laser bonding pads are configured to create a high thermal conductivity path from the optical gain section of the EML to a silicon photonic substrate heat sink of the silicon photonic chip, and the modulator bonding pads and the heater bonding pads are configured to create a low thermal conductivity path from the integrated resistive heater and the absorption section of the EML to the silicon photonic substrate heat sink.

According to another aspect, a chip hosting a monolithic EML array is provided. In an example embodiment, the chip includes a substrate; and an array of electro-absorption modulated lasers (EMLs) disposed on the substrate. Each EML of the array of EMLs includes an optical gain section comprising a gain section number of quantum well layers; and an absorption section comprising an absorption section number of quantum well layers. The absorption section number of quantum well layers is larger than the active section number of quantum well layers. A laser cavity comprising the optical gain section is defined by a first Bragg grating disposed between the optical gain section and the absorption section.

In an example embodiment, the chip is flip-chip bonded to a silicon photonics carrier.

In an example embodiment, the array of EMLs is a coarse wavelength division multiplexing (CWDM) array and a respective emission wavelength of each EML of the array of EMLs is controlled by a period of the respective first Bragg grating of the EML.

According to another aspect, a coarse wavelength division multiplexing (CWDM) array chip is provided. In an example embodiment, the CWDM array chip includes a CWDM source chip including a substrate; and an array of electro-absorption modulated lasers (EMLs) disposed on the substrate. Each EML of the array of EMLs includes an optical gain section comprising a gain section number of quantum well layers; and an absorption section comprising an absorption section number of quantum well layers. The absorption section number of quantum well layers is larger than the active section number of quantum well layers. A laser cavity including the optical gain section is defined, in part, by a first Bragg grating disposed between the optical gain section and the absorption section. The CWDM source chip further includes a silicon photonics carrier. The CWDM source chip is flip-chip bonded to the silicon photonics carrier. The array of EMLs is a coarse wavelength division multiplexing (CWDM) array and a respective emission wavelength of each EML of the array of EMLs is controlled by a period of the respective first Bragg grating of the EML. The photonics carrier comprises an array waveguide grating (AWG) combiner which combines optical signals generated by respective EMLs of the array of EMLs into a single optical output.

According to another aspect, an optical interconnect is provided. In an example embodiment, the optical link includes a first transceiver and a second transceiver in optical communication with one another via one or more optical fibers. The first transceiver comprises one or more EMLs.

In an example embodiment, the first transceiver comprises an array of EMLs.

In an example embodiment, the first transceiver comprises an array of EMLs configured as a WDM array.

According to another aspect, a datacenter is provided. In an example embodiment, the datacenter includes at least one optical interconnect, the at least one optical interconnect includes at least one (short cavity, GaAs-based) EML.

### BRIEF DESCRIPTION OF THE SEVERAL VIEWS OF THE DRAWINGS

Reference will now be made to the accompanying drawings, which are not necessarily drawn to scale, and wherein:

FIG. 1 provides a schematic cross-sectional diagram of an example EML taken in a first plane perpendicular to a surface of a substrate on which the EML is disposed, in accordance with certain embodiments;

FIG. 2 provides a schematic top view diagram of another example EML taken in a second plane that is parallel to a surface of a substrate on which the EML is disposed, in accordance with certain embodiments;

FIG. 3 provides a schematic top view diagram of another example EML taken in a second plane that is parallel to a surface of a substrate on which the EML is disposed, in accordance with certain embodiments;

FIG. 4 provides a schematic top view diagram of another example EML taken in a second plane that is parallel to a surface of a substrate on which the EML is disposed, in accordance with certain embodiments;

FIG. 5 provides a schematic top view diagram of another example EML taken in a second plane that is parallel to a surface of a substate on which the EML is disposed, in accordance with certain embodiments;

FIG. 6 provides a plot illustrating the use of the stop bands of two Bragg gratings of the EML to define and/or control the optical mode emitted by an EML, in accordance with certain embodiments;

FIG. 7 schematically illustrates the flip-chip bonding of an EML chip to a silicon photonics chip, in accordance with certain embodiments;

FIG. 8 provides a schematic diagram of an example array of EMLs configured as a wavelength division multiplexing (WDM) source, in accordance with certain embodiments;

FIG. 9 provides a schematic diagram of a monolithic WDM array flip-chip bonded onto a silicon photonics chip including an arrayed waveguide grating (AWG) device, in accordance with certain embodiments;

FIG. 10 provides a block diagram of an optical interconnect including an array of EMLs, according to certain embodiments;

FIG. 11 provides a block diagram of an example system that may include one or more optical interconnects including EMLs, according to certain embodiments;

FIG. 12 provides a schematic diagram of an example datacenter that may include one or more optical interconnects according to certain embodiments;

FIG. 13 provides a block diagram of two example communication devices in communication with one another according to certain embodiments;

FIGS. 14A and 14B illustrate a top view and a perspective view, respectively, of a transceiver module operatively coupled to a network adapter, in accordance with an embodiment of the disclosure.

FIG. 15 depicts some exemplary scenarios for use of an optical transceiver, in accordance with various embodiments;

FIG. 16 provides a block diagram that schematically illustrates a computing system that may include one or more optical interconnects of various embodiments;

FIG. 17 illustrates an example computing environment, in accordance with at least one embodiment;

FIG. 18 illustrates another example computer system that may include optical interconnects, according to at least one embodiment; and

FIG. 19 is a block diagram that schematically illustrates a co-packaged Networking Device, in accordance with an embodiment that is disclosed herein.

### DETAILED DESCRIPTION

The present disclosure more fully describes various embodiments with reference to the accompanying drawings. It should be understood that some, but not all embodiments are shown and described herein. Indeed, the embodiments may take many different forms, and accordingly this disclosure should not be construed as limited to the embodiments set forth herein. Rather, these embodiments are provided so that this disclosure will satisfy applicable legal requirements. Like numbers refer to like elements throughout.

Various embodiments provide short cavity electro-absorption modulated lasers (EMLs). The laser of the EML is referred to as a short cavity laser because the laser cavity and/or resonator has a length that is no more than 100 microns. For example, the length of the optical cavity of an example EML may be in a range of 20 to 50 microns.

According to various embodiments, an EML includes an optical gain section and an absorption section. For example, an EML may include a ridge waveguide that includes a core that includes an optical gain section and an absorption section. The optical gain section includes a gain section number of quantum well layers configured for generating light. The absorption section includes an absorption section number of quantum well layers configured for absorbing light in accordance with an electrical control signal applied thereto. The absorption section number is greater than the gain section number. For example, the gain section number may be in a range of two to five and the absorption section number may be in a range of ten to twenty, in an example embodiment.

In various embodiments, the EML includes a laser cavity that includes the optical gain section. In certain embodiments, the laser cavity is defined, at least in part, by a first Bragg grating disposed between the optical gain section and the absorption section. In some embodiments, a second Bragg grating is disposed on the longitudinally opposite end of the laser cavity, with respect to the first Bragg grating. In some embodiments, a mirror, such as a cleaved mirror that may include a high reflectivity coating is disposed on the longitudinally opposite end of the laser cavity, with respect to the first Bragg grating. The laser cavity is longitudinally defined by the first Bragg grating and either a second Bragg grating or a mirror such as a cleaved mirror that may include a high reflectivity coating, in various embodiments.

In some embodiments, a distributed feedback grating is disposed within the optical gain section and/or disposed laterally on one or more sides of the optical gain section. The distributed feedback grating is optically coupled to an optical mode propagating in the optical gain section. A distributed feedback grating is a periodic structure that is optically coupled (directly or evanescently) to the laser cavity. The distributed feedback grating reflects light back into the laser cavity, which helps to ensure that the laser output is single-frequency and/or optical mode.

In some embodiments, the first Bragg grating defines a first stop band. If a second Bragg is present, the second Bragg grating defines a second stop band. If a distributed feedback grating is present, the distributed feedback grating defines a feedback stop band. In some embodiments, the first stop band and the second stop band or the feedback stop band are offset from one another such that the off set in the first stop band and the second stop band or the feedback stop band cause the laser of the EML to operate in and/or emit a single optical mode or wavelength. In some embodiments, a distribute feedback grating of the EML includes a quarter wavelength phase shift to confine the optical mode of the laser of the EML and/or to cause the laser of the EML to operate in and/or emit a single optical mode or wavelength.

In various embodiments, a plurality of EMLs are incorporated into an array of EMLs. Each EML of the array of EMLs may be configured to emit a respective laser beam (or modulated laser beam) characterized by a different wavelength. For example, no two EMLs of the array of EMLs may emit laser beams that are characterized by the same wavelength. For example, characteristics of the laser cavities of the EMLs of the array (e.g., first Bragg gratings, second Bragg gratings, distributed feedback gratings, and/or the like) may be configured such that each EML of the array of EMLs emit a respective continuous wave (CW) laser beam (or modulated laser beam) characterized by a different wavelength. In some embodiments, the array of EMLs is configured as a WDM (e.g., coarse WDM or dense WDM) source.

Optical links are often used in large datacenters to communication data quickly between various portions of the datacenter. These optical links require an optical source, such as a laser, for generating the optical signals. Bandwidth requirements for these lasers continue to increase beyond currently achievable bandwidths and power consumption requirements continue to decrease beyond currently achievable power consumption. For example, while VCSELs can efficiently provide laser signals with very low power consumption, direct modulation requirements prevent the modulation bandwidth of VCSELs from exceeding 50-70 GHz. Conventional EML lasers tend to have higher bandwidth but low wall plug efficiency. Therefore, technical problems exist regarding providing optical sources and/or EMLs capable of next generation bandwidth and low power requirements.

Various embodiments provide technical solutions to these technical challenges. In various embodiments, short cavity electro-absorption modulated lasers (EMLs) are provided having small threshold currents and high differential quantum efficiency by optimizing the active length and area. For example, in an example embodiment, the optical gain section of an EML has a threshold current of 1.3 mA and an efficiency of 0.68. Moreover, the modulator section is configured to be driven using a differential electrical signal. For example, the number of quantum well layers of the absorption section may be increased compared to the number of quantum well layers in the optical gain section. For example, the absorption section may include ten or more quantum well layers. This enables the modulator to be driven using a differential electrical signal of low voltage swing. In an example embodiment, the modulator is configured to be driven by a radio frequency (RF) electrical signal having a differential voltage swing of less than 1 Volt. Additionally, the modulator may be configured as a travelling wave electro-absorption modulator (TW-EAM) or a segmented EAM. This results in an EML having high bandwidth (e.g., greater than 80 GHz) and high extinction ratio.

Therefore, various embodiments provide technical improvements to the fields of semiconductor lasers, EMLs, EML arrays, WDM array sources, optical links, datacenters, and/or the like.

### Example Short Cavity Electro-Absorption Lasers (EMLs)

The power consumption associated with an EML is arising from the direct current (DC) power needed to operate the laser, and from the radiofrequency (RF) driver generating the RF signal which is driving the optical modulator. The RF driver power consumption is generally proportional to the voltage swing amplitude needed by the electro-absorption modulator (EAM) of the EML to provide an appropriate extinction ratio. The RF driver power consumption is also proportional to the amount of DSP needed for acceptable signal integrity, and can be minimized by increasing optical bandwidth. Therefore, reducing the power consumption of the EML transmitter may be achieved by reducing the EAM voltage swing requirements and by increasing its bandwidth. The modulator also presents some optical loss which requires the laser of the EML to produce higher optical power compared to direct modulation (VCSELs). Thus, it is desirable for an EML to employ a laser with high wall plug efficiency. Moreover, conventional InP based EMLs exhibit high power consumption due to their high threshold current and low wall plug efficiency. This is partly due to the long laser cavity (300-400 um) typically being used, and to the inherent properties of the InP-based material system.

A major problem relating to all telecom semiconductor lasers is how to ensure the laser is operating with a single optical mode. In vertical cavity surface emitting lasers (VCSELs) this is done mainly by limiting the aperture size, and by some means to control the polarization. In edge emitting lasers, polarization is not an issue. The lateral mode is controlled by the ridge width of the ridge waveguide of the laser and the proximity of the ridge waveguide to the core (multi-quantum well (MQW)) waveguide layers in the mesa structure on which the ridge waveguide is disposed. For short cavity lasers described herein, the situation is somewhat different, and single longitudinal mode control can be obtained by other means. For example, the stop band of a grating is defined as the spectral reflection wavelength band where it is reflecting. The spectrum of an example GaAs based EML may have a 6 nm wide stop band containing seven longitudinal cavity modes. However, for short cavity lasers (e.g., having cavity length less than 100 microns, or less than 50 microns) the ratio between the stop band width and the cavity mode spacing is much smaller. The reduction of number of cavity modes fitting inside the stop band can be used to make the laser single mode.

Various embodiments of the present disclosure provide technical solutions to these problems by using short cavity EMLs, which are GaAs based in some embodiments, that operate with a single optical mode, with low power consumption for both the laser and modulator driver and that may be incorporated into EML arrays to provide CWDM sources.

In various embodiments, short cavity GaAs-based EMLs are provided having a spectral wavelength range of 750-1130 nm. Such EMLs may be used as optical sources for short to mid-length interconnect optical links (<2km). Fiber dispersion, which occurs due to different velocities of signal components over long distances, can deteriorate the signal, especially over distances greater than 10 kilometers or even 1-2 kilometers at high speeds. For long distances, the 1310 nanometers wavelength is preferred due to low dispersion. However, for short distances, especially less than 300 meters, dispersion is more tolerable, allowing the use of gallium arsenide (GaAs) wavelengths (750 to 1130 nanometers). EMLs of various embodiments are configured to operate with low DC electrical power consumption (<50 mW) and low RF modulation power. The laser DC power consumption is determined by the required optical output power and wall plug efficiency. Using the basic laser equations:

Iₜₕ=1/β*A*[1/L*ln(1/R)+α]

where Iₜₕ is the threshold current of the laser cavity, R=SQRT(R1*R2) is the geometrical average of the mirror reflectivity of a first mirror/reflector of the laser cavity having reflectivity R1 and a second mirror/reflector of the laser cavity having reflectivity R2, α is the loss for unit length, A is the active area of the optical gain section, β is the gain coefficient per current density in cm/ampere, and L is the active cavity length. Also, for the differential quantum efficiency η:

η=ln(1/R)/[ln(1/R)+α*L].

As an example, using conservative parameters derived from the literature for the laser constants α and β and from simulations at laser wavelength of 980 nm we have α=16 cm⁻¹, β=0.024 cm/Amp, R=0.92, L=25 um, active width=3 um, drive current 20 mA and drive voltage 2.25V we obtain Iₜₕ=1.3 mA, η=0.68, and wall plug efficiency is 0.37 for an output power of 16.5 mW and a DC power consumption of 45 mW. The relatively high output power (compared to VCSELs) can compensate for the insertion loss of the integrated EAM of the EML, so the modulated optical signal can have the required average power sufficient for the optical link. EMLs of various embodiments, thus reduce the laser DC power consumption by a large factor (>3) compared to InP-based EMLs, and makes it possible for EMLs to compete with the DC performance of low power consumption VCSELs

To ensure single longitudinal mode operation of the laser of the (short cavity) EML there are several options that may differ from long cavity laser configurations. One option is a short cavity EML laser where the mirrors/reflectors that define the longitudinal ends of the laser cavity are both Bragg gratings and/or distributed Bragg reflectors (DBRs) (the terms Bragg grating and Bragg reflector/DBR are used interchangeably herein). In various embodiments, one or both of the Bragg gratings may be or be similar to a Bragg reflector or high-contrast grating disclosed by U.S. application Ser. No. 19/200,806, filed May 7, 2025, and titled “OPTICAL RIDGE WAVEGUIDE DEVICES WITH HIGH CONTRAST WAVEGUIDE GRATINGS AND METHODS OF FABRICATION THEREOF,” the contents of which are incorporated herein by reference in their entirety.

To ensure single mode operation with this option, the combined stop band of the Bragg gratings is tailored to have an overlap that is smaller than the cavity mode spacing. For example, the Bragg wavelength of the two Bragg gratings that longitudinally define the laser cavity of the EML may be slightly offset from one another. The stop band (SB) of a Bragg grating is given by

SB=κλ_{b}²/(πn_{g}),

where κ is the coupling coefficient of the Bragg grating in cm⁻¹, λ_{b} is the Bragg wavelength of the Bragg grating and ng is the group refractive index of the waveguide.

The mode spacing of the cavity δλ is given by

δλ=λ²/[2n_{g}(L_{active}+L_{eff1}+L_{eff2})]

where λ is the free space wavelength, L_{active} is the length of the optical gain section and L_{eff1} and L_{eff2} are the effective lengths of the two gratings as given by:

L_{eff}=1/(2κ) tan h(κLg)

where Lg is the (physical) grating length. For the example short cavity EML described above, and with κ=1000 cm⁻¹ and with front and back grating lengths of 25 and 50 um, respectively, and active gain length of 25 um, the laser would have an effective length L_{active} +L_{eff1} +L_{eff2} of 35 um. Also the cavity mode spacing is 4.0 nm and a stop band width is 8.9 nm. Therefore, by changing the grating periods of one of the Bragg gratings with respect to the other Bragg grating, and offsetting the Bragg wavelength of one of the gratings by 5.1 nm compared to the other Bragg grating, the stop bands will overlap by only 3.8 nm. As the overlap is less than the cavity mode spacing, this ensures that only one cavity mode can exist within the combined stop band.

In another example embodiment, the optical gain section contains a distributed feedback (DFB) grating that can have, for example, a ¼ wavelength phase shift. The DFB grating located inside the gain waveguide ridge can be a weaker (low contrast) compared to the high contrast back and front Bragg gratings that longitudinally define the laser cavity length. For example, the periodic alternating regions of the high contrast back and front Bragg gratings may have a refractive index difference or contrast of 1.5 or more (e.g., 1.5 to 2.4) and the periodic alternating regions of the low contrast DFB grating may have a refractive index difference or contrast of less than 1.5. Alternatively, the DFB grating can be a high contrast double grating located on the sides of the ridge and laterally coupled to the optical mode propagating inside the waveguide ridge.

Another example embodiment of a (short cavity, GaAs-based) EML includes a back mirror/reflector that includes high reflectivity (HR) thin film coated cleaved mirror. The back mirror facet can be formed by a standard bar cleaving process, or alternatively by inductively coupled plasma (ICP) vertical etching or by a micro-cleaving process. For example, the laser cavity may be longitudinally defined by a back mirror/reflector in the form of a cleaved, micro-cleaved, or etched facet and a front mirror/reflector (disposed between the optical gain section and the absorption section of the EML) in the form of a (high-contrast) Bragg grating. For example, the high reflectivity required by the short cavity is provided by the strong DBR grating and the high reflectivity coated cleaved mirror at the back side of the laser. The EML may further include a single longitudinal mode due to a ¼ wavelength shifted DFB grating that forms part of the laser cavity.

In various embodiments, the modulator RF driver power consumption is also reduced compared to conventional EMLs. The modulator RF driver power consumption is proportional to the RF voltage swing needed to obtain the required dynamic extinction ratio (ER) of the modulator. Therefore, to minimize the modulator power consumption, EMLs of various embodiments include the modulators with both high ER slope efficiency (dB/V), and high RF modulation bandwidth simultaneously. The modulators of various embodiments are short modulators that have high optical confinement factor, use a large number (>10) of quantum well layers. In certain embodiments, the modulator includes several short active modulator segments with high optical confinement factors integrated sequentially on the optical waveguide, in a traveling wave EAM (TW-EAM) configuration. In some embodiments, the modulator RF drive power consumption is reduced by using a short cavity laser integrated with a differential drive (DD) EAM. Such embodiments provide an improvement (over conventional EAMs) because the differential driver tends to require a lower power consumption compared to a single ended driver for the same output voltage swing.

In some embodiments, the modulator RF voltage swing is reduced (compared to conventional EAMs)—thus reducing the power consumption of the modulator driver—by employing an integrated resistive heater on the EML chip located near to the modulator waveguide and having a good thermal contact with the modulator

The required drive voltage swing and the insertion loss of the modulator depend critically on the difference between the laser wavelength and the wavelength corresponding to the modulator bandgap. This wavelength difference is known as the EML detuning and it varies with the temperature due to the temperature dependence of the modulator bandgap. For the optimal performance of the modulator, a specific detuning should be maintained. Therefore, by maintaining the modulator at a constant temperature corresponding to an operating temperature range (e.g., the maximum temperature of the ambient temperature range (Tₘₐₓ)). In this way the modulator area is locally heated to bring the modulator to Tₘₐₓ whenever the ambient temperature of the environment around the modulator is cooler than Tₘₐₓ. By adding the integrated heater, the EML can be designed to always be near the optimal detuning point, and therefore to have the lowest voltage swing needed to achieve the required performance (extinction ratio, linearity, and optical modulation amplitude) regardless of the large ambient temperature range of the surroundings. The resistive heater should efficiently heat the modulator area but should not affect the laser area to avoid degrading the laser performance.

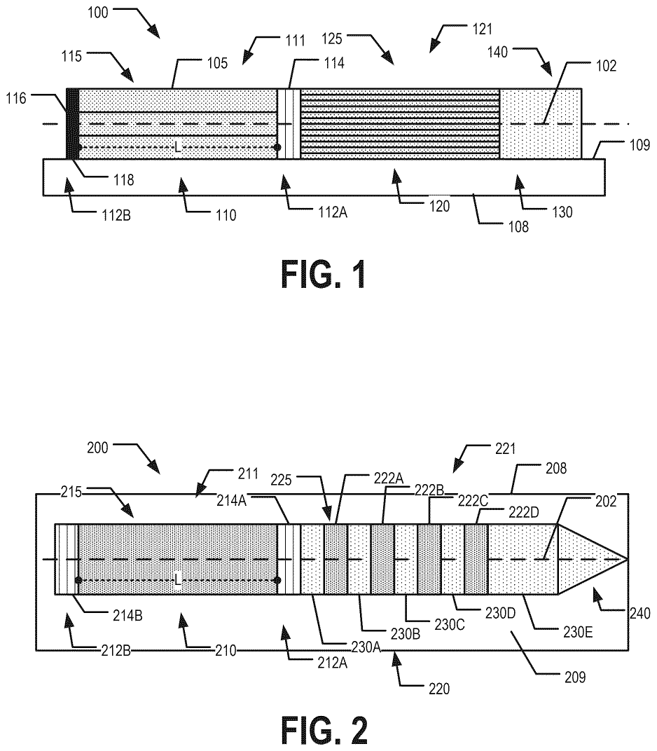

FIGS. 1-5 illustrate some examples of EMLs 100, 200, 300, 400, 500, according to various embodiments. FIG. 1 illustrates a schematic cross-sectional diagram of an example EML 100 taken in a first plane perpendicular to a surface 109 of a substrate 108 on which the EML 100 is disposed, in accordance with certain embodiments. The EML 100 comprises an optical gain section 110 and an absorption section 120. The optical gain section 110 and the absorption section 120 each comprise a plurality of quantum well layers 105 (e.g. stack of quantum wells grown epitaxially). The optical gain section 110 includes a gain section number of quantum wells 115. The absorption section 120 includes an absorption section number of quantum wells 125. In various embodiments, the absorption section number is greater than the gain section. For example, in certain embodiments, the gain section number is in a range of two to five. For example, the optical gain section 110 may include two to five quantum well layers 105. In certain embodiments, the absorption section number is ten or greater. For example, the absorption section 120 may include ten to twenty quantum well layers 105, in various embodiments.

In various embodiments, the EML 100 comprises a laser cavity 111 that extends from a first end 112A to a second end 112B. The optical gain section 110 is disposed within the laser cavity 111. In various embodiments, the laser cavity 111 has a cavity length L measured parallel to a longitudinal axis 102 of the EML. In various embodiments, the cavity length L is less than 100 microns. In certain embodiments, the cavity length L is forty microns or less (e.g., 20-35 microns).

The first end 112A of the optical cavity 111 is defined by a first Bragg grating 114. The first Bragg grating 114 is disposed between the optical gain section 110 and the absorption section 120. In an example embodiment, the first Bragg grating 114 a high-contrast grating.

The second end 112B of the optical cavity 111 is disposed longitudinally on an opposite side of the optical gain section 110 of the first Bragg grating 114. For the EML 100, the second end 112B is defined by a mirror, such as cleaved mirror 116. In some embodiments, the cleaved mirror 116 has a high reflectivity coating 118 applied thereto. The high reflectivity coating 118 may include a reflective metallic coating and/or a dielectric coating including a periodic effective refractive index. For example, the cleaved mirror 116 and the first Bragg grating 114 longitudinally define the optical cavity 111.

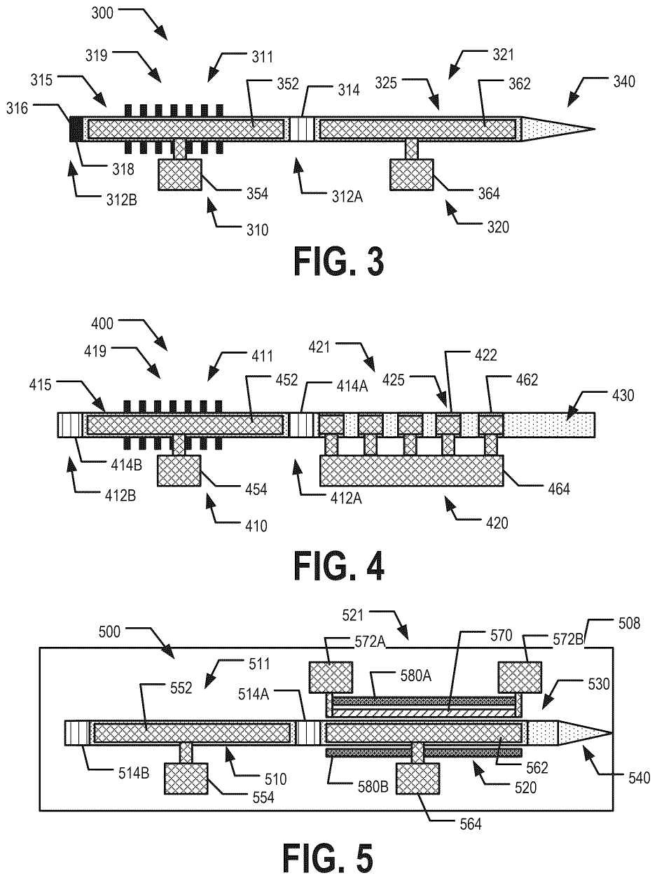

In various embodiments, the EML 100 is configured to emit light and/or a modulated optical signal along the longitudinal axis 102 of the EML 100. For example, the optical gain section 110 is driven and/or has current inserted therein (e.g., via a laser electrode not shown if FIG. 1, but possibly similar to laser electrode 352, 452, 552 shown in FIGS. 3, 4, and 5, respectively). An optical signal is emitted from the laser cavity 111 via the first Bragg grating 114. The optical signal is modulated via the modulator 121 comprising the absorption section 120 to provide a modulated optical signal to the waveguide 130. For example, the modulator 121 may be driven by a modulator driving signal via a modulator electrode (not shown in FIG. 1, but possibly similar to modulator electrode 362, 562 shown in FIGS. 3 and 5, respectively). In various embodiments, the modulator 121 is driven by a differential signal. For example, the modulator 121 may be driven by a radio frequency (RF) electrical signal.

In various embodiments, the waveguide 130 provides the modulated optical signal to a spot size converter 140. In various embodiments, the spot size converter 140 is a lithographically defined waveguide configured to reduce the mode field of the modulated optical signal. For example, the waveguide 130 and/or the spot size converter 140 may provide the modulated optical signal to an optical fiber, another waveguide of a silicon photonics platform, a multiplexer, and/or the like.

FIG. 2 illustrates a schematic cross-sectional diagram of an example EML 200 taken in a second plane that is parallel to a surface 209 of a substrate 208 on which the EML 200 is disposed, in accordance with certain embodiments. The EML 200 comprises an optical gain section 210 and an absorption section 220. The optical gain section 210 and the absorption section 220 each comprise a plurality of quantum well layers. The optical gain section 210 includes a gain section number of quantum wells 215. The absorption section 220 includes an absorption section number of quantum wells 225. In various embodiments, the absorption section number is greater than the gain section. For example, in certain embodiments, the gain section number is in a range of two to five. For example, the optical gain section 210 may include two to five quantum well layers. In certain embodiments, the absorption section number is ten or greater. For example, the absorption section 220 may include ten to twenty quantum well layers, in various embodiments.

In various embodiments, the EML 200 comprises a laser cavity 211 that extends from a first end 212A to a second end 212B. The optical gain section 210 is disposed within the laser cavity 211. In various embodiments, the laser cavity 211 has a cavity length L measured parallel to a longitudinal axis 202 of the EML. In various embodiments, the cavity length L is less than 100 microns. In certain embodiments, the cavity length L is forty microns or less (e.g., 20-35 microns).

The first end 212A of the optical cavity 211 is defined by a first Bragg grating 214A. The first Bragg grating 214A is disposed between the optical gain section 210 and the absorption section 220. In an example embodiment, the first Bragg grating 214A is a Bragg reflector or high-contrast grating. The second end 212B of the optical cavity 211 is disposed longitudinally on an opposite side of the optical gain section 210 of the first Bragg grating 214A. For the EML 200, the second end 212B is defined by a second Bragg grating 214B. In various embodiments, the reflectivity of the second Bragg grating 214B is greater than the reflectivity of the first Bragg grating 214A. For example, a Bragg grating comprises periodic alternating regions of characterized by different refractive indices. In various embodiments, the second Bragg grating 214B may include a larger number of periodic alternating regions than the first Bragg grating 214A.

In various embodiments, the EML 200 is configured to emit light and/or a modulated optical signal along the longitudinal axis 202 of the EML 200. For example, the optical gain section 210 is driven and/or has current inserted therein (e.g., via a laser electrode not shown if FIG. 1, but possibly similar to laser electrode 352, 452, 552 shown in FIGS. 3, 4, and 5, respectively). An optical signal is emitted from the laser cavity 211 via the first Bragg grating 214A. The optical signal is modulated via the modulator 221 comprising the absorption section 220 to provide a modulated optical signal.

In the example EML 200 illustrated in FIG. 2, the modulator 221 comprises a segmented absorption section 220. For example, the modulator 221 comprises a plurality of passive waveguide segments 230A-230E that are interleaved between absorption segments 222A-222D. For example, the modulator 221 may be a segmented modulator such as a travelling wave electro-absorption modulator (TW-EAM). In various embodiments, the absorption segments 222 (e.g., 222A-222D) each comprise the absorption number of quantum well layers and are each driven by a respective segment of a segmented modulator electrode. For example, the modulator 221 may be driven by a modulator driving signal via a segmented modulator electrode (not shown in FIG. 2, but possibly similar to segmented modulator electrode 462 shown in FIG. 4). In various embodiments, the modulator 221 is driven by a differential signal. For example, the modulator 221 may be driven by a radio frequency (RF) electrical signal. In various embodiments, the waveguide segments 230 (230A-230D) may include quantum well layers that are not directly driven (e.g., are located between the electrode segments of a segmented modulator electrode) or may be passive optical waveguide segments that include a passive waveguide material configured to confine and/or guide an optical mode (e.g., via a refractive index contrast between the passive waveguide material and cladding thereabout). For example, the passive waveguide material may comprise GaAlAs and/or another waveguide material.

In various embodiments, the modulator 221 provides the modulated optical signal to a final waveguide segment 230E. In various embodiments, the final waveguide segment 230E provides the modulated optical signal to a spot size converter 240. In various embodiments, the spot size converter 240 is a lithographically defined waveguide configured to increase the mode field of the modulated optical signal. For example, the final waveguide segment 230E and/or the spot size converter 240 may provide the modulated optical signal to an optical fiber, another waveguide of a silicon photonics platform, a multiplexer, and/or the like.

FIG. 3 illustrates a schematic top view diagram of an example EML 300 taken in a second plane that is parallel to a surface of a substrate (not shown) on which the EML 300 is disposed, in accordance with certain embodiments. The EML 300 comprises an optical gain section 310 and an absorption section 320. The optical gain section 310 and the absorption section 320 each comprise a plurality of quantum well layers. The optical gain section 310 includes a gain section number of quantum wells 315. The absorption section 320 includes an absorption section number of quantum wells 325. In various embodiments, the absorption section number is greater than the gain section. For example, in certain embodiments, the gain section number is in a range of two to five. For example, the optical gain section 310 may include two to five quantum well layers. In certain embodiments, the absorption section number is ten or greater. For example, the absorption section 320 may include ten to twenty quantum well layers, in various embodiments.

In various embodiments, the EML 300 comprises a laser cavity 311 that extends from a first end 312A to a second end 312B. The optical gain section 310 is disposed within the laser cavity 311. In various embodiments, the laser cavity 311 has a cavity length L measured parallel to a longitudinal axis of the EML. In various embodiments, the cavity length L is less than 100 microns. In certain embodiments, the cavity length L is forty microns or less (e.g., 20-35 microns).

The first end 312A of the optical cavity 311 is defined by a first Bragg grating 314. The first Bragg grating 314 is disposed between the optical gain section 310 and the absorption section 320. In an example embodiment, the first Bragg grating 314 is or is similar to a Bragg reflector or high-contrast grating.

The second end 312B of the optical cavity 311 is disposed longitudinally on an opposite side of the optical gain section 310 of the first Bragg grating 314. For the EML 300, the second end 312B is defined by a mirror, such as cleaved mirror 316. In some embodiments, the cleaved mirror 316 has a high reflectivity coating 318 applied thereto. For example, the cleaved mirror 316 and the first Bragg grating 314 longitudinally define the optical cavity 311.

In various embodiments, one or more distributed feedback gratings 319 are disposed within the laser cavity 311 or are disposed laterally on one or more sides of the laser cavity 311 so as to be laterally coupled to an optical mode propagating in the optical gain section 310. As used herein, the lateral direction is perpendicular to the longitudinal axis of the EML (which is aligned with the light emission direction of the optical cavity) and parallel to a surface of the substrate on which the EML is disposed. A distributed feedback grating is a periodic structure that is optically coupled (directly or evanescently) to the laser cavity. For example, the distributed feedback grating 319 may be a gain section distributed feedback Bragg grating, which is a distributed feedback Bragg grating that is etched into and/or defined in the optical gain section 310. In another example, the distributed feedback grating 319 may be a laterally coupled distributed feedback Bragg grating, which is a distributed feedback Bragg grating that is etched into and/or defined in a layer laterally adjacent to the optical gain section 310. The distributed feedback grating 319 may reflect light back into the laser cavity, which helps to ensure that the laser output is single-frequency and/or longitudinal optical mode. For example, in some embodiments, a distributed feedback grating 319 includes a quarter wavelength phase shift to confine the optical mode of the laser cavity 311 of the EML 300 and/or to cause the laser cavity 311 of the EML 300 to operate in and/or emit a single longitudinal optical mode or wavelength.

In various embodiments, the EML 300 is configured to emit light and/or a modulated optical signal along the longitudinal axis of the EML 300. For example, the optical gain section 310 is driven and/or has current inserted therein via a laser electrode 352. For example, a laser driving signal may be provided to the laser pad 354. The laser driving DC current may then be provided to the laser electrode 352 via an electrically conductive path provided between laser pad 354 and the laser electrode 352.

The optical signal is modulated via the modulator 321 comprising the absorption section 320 to provide a modulated optical signal to the spot size converter 340. For example, the modulator 321 may be driven by a modulator driving signal via a modulator electrode 362. For example, a modulator driving signal may be provided to a modulator pad 364. The modulator driving signal may then be provided to the modulator electrode 362 via an electrically conductive path provided between the modulator pad 364 and the modulator electrode 362. In various embodiments, the modulator 321 is driven by a differential signal. For example, the modulator driving signal may be a single ended or a differential radio frequency (RF) electrical signal.

In various embodiments, the spot size converter 340 is a lithographically defined waveguide configured to increase the mode field size of the modulated optical signal. For example, the spot size converter 340 may provide the modulated optical signal to an optical fiber, another waveguide of a silicon photonics platform, a multiplexer, and/or the like.

FIG. 4 illustrates a schematic top view diagram of an example EML 400 taken in a second plane that is parallel to a surface of a substrate (not shown) on which the EML 400 is disposed, in accordance with certain embodiments. The EML 400 comprises an optical gain section 410 and an absorption section 420. The optical gain section 410 and the absorption section 420 each comprise a plurality of quantum well layers. The optical gain section 410 includes a gain section number of quantum wells 415. The absorption section 420 includes an absorption section number of quantum wells 425. In various embodiments, the absorption section number is greater than the gain section. For example, in certain embodiments, the gain section number is in a range of two to five. For example, the optical gain section 410 may include two to five quantum well layers. In certain embodiments, the absorption section number is ten or greater. For example, the absorption section 420 may include ten to twenty quantum well layers, in various embodiments.

In various embodiments, the EML 400 comprises a laser cavity 411 that extends from a first end 412A to a second end 412B. The optical gain section 410 is disposed within the laser cavity 411. In various embodiments, the laser cavity 411 has a cavity length L measured parallel to a longitudinal axis of the EML. In various embodiments, the cavity length L is less than 100 microns. In certain embodiments, the cavity length L is forty microns or less (e.g., 20-35 microns).

The first end 412A of the optical cavity 411 is defined by a first Bragg grating 414A. The first Bragg grating 414A is disposed between the optical gain section 410 and the absorption section 420. In an example embodiment, the first Bragg grating 414A is a Bragg reflector or high-contrast grating. The second end 412B of the optical cavity 411 is disposed longitudinally on an opposite side of the optical gain section 410 of the first Bragg grating 414A. For the EML 400, the second end 412B is defined by a second Bragg grating 414B. In various embodiments, the reflectivity of the second Bragg grating 414B is greater than the reflectivity of the first Bragg grating 414A. For example, a Bragg grating comprises periodic alternating regions of characterized by different refractive indices. In various embodiments, the second Bragg grating 414B may include a larger number of periodic alternating regions than the first Bragg grating 414A.

In various embodiments, one or more distributed feedback gratings 419 are disposed within the laser cavity 411 or are disposed laterally on one or more sides of the laser cavity 411 so as to be laterally coupled to an optical mode propagating in the optical gain section 410. As used herein, the lateral direction is perpendicular to the longitudinal axis of the EML (which is aligned with the light emission direction of the optical cavity) and parallel to a surface of the substrate on which the EML 400 is disposed. A distributed feedback grating is a periodic structure that is optically coupled (directly or evanescently) to the laser cavity. For example, the distributed feedback grating 419 may be etched into and/or defined in the optical gain section 410. In another example, the distributed feedback grating 419 may be etched into and/or defined in a layer laterally adjacent to the optical gain section 410. The distributed feedback grating 419 may reflect light back into the laser cavity, which helps to ensure that the laser output is single-frequency and/or optical mode. For example, in some embodiments, a distributed feedback grating 419 includes a quarter wavelength phase shift to confine the optical mode of the laser cavity 411 of the EML 400 and/or to cause the laser cavity 411 of the EML 400 to operate in and/or emit a single longitudinal optical mode or wavelength.

In various embodiments, the EML 400 is configured to emit light and/or a modulated optical signal along the longitudinal axis of the EML 400. For example, the optical gain section 410 is driven and/or has current inserted therein via a laser electrode 452. For example, a laser driving DC current may be provided to the laser pad 454. The laser driving signal may then be provided to the laser electrode 452 via an electrically conductive path provided between laser pad 454 and the laser electrode 452.

The optical signal is modulated via the modulator 421 comprising the absorption section 420 to provide a modulated optical signal. In the example EML 400 illustrated in FIG. 4, the modulator 421 comprises a segmented absorption section 420. For example, the modulator 421 comprises a plurality of passive waveguide segments 430 that are interleaved between absorption segments 422. For example, the modulator 421 may be a segmented modulator such as a travelling wave electro-absorption modulator (TW-EAM). In various embodiments, the absorption segments 422 each comprise the absorption number of quantum well layers and are each driven by a respective segment of a segmented modulator electrode 462. For example, the modulator 421 may be driven by a modulator driving signal via a segmented modulator electrode 462. For example, a modulator driving signal may be provided to a modulator pad 464. The modulator driving signal is provided to the electrode segments of the segmented modulator electrode 462 via electrically conductive paths from the modulator pad 464 to the electrode segments of the segmented modulator electrode 462. In various embodiments, the modulator driving signal is a differential signal. For example, the modulator 421 may be driven by a radio frequency (RF) electrical signal. In various embodiments, the waveguide segments 430 may include quantum well layers that are not directly driven (e.g., are located between the electrode segments of a segmented modulator electrode) or may comprise a passive waveguide material configured to confine and/or guide an optical mode (e.g., via a refractive index contrast between the passive waveguide material and cladding thereabout). For example, the passive waveguide material may comprise GaAlAs and/or another waveguide material.

In various embodiments, the modulator 421 provides the modulated optical signal to a final waveguide segment 430. The final waveguide segment 430 provides the modulated optical signal to a spot size converter. For example, the final waveguide segment 430 and/or the spot size converter may provide the modulated optical signal to an optical fiber, another waveguide of a silicon photonics platform, a multiplexer, and/or the like.

FIG. 5 illustrates a schematic top view diagram of an example EML 500 having a heater 570 integrated with the modulator 521. The diagram of the EML 500 is taken in a second plane that is parallel to a surface 509 of a substrate 508 on which the EML 500 is disposed. The EML 500 comprises an optical gain section 510 and an absorption section 520. The optical gain section 510 and the absorption section 520 each comprise a plurality of quantum well layers. The optical gain section 510 includes a gain section number of quantum wells. The absorption section 520 includes an absorption section number of quantum wells. In various embodiments, the absorption section number is greater than the gain section. For example, in certain embodiments, the gain section number is in a range of two to five. For example, the optical gain section 510 may include two to five quantum well layers. In certain embodiments, the absorption section number is ten or greater. For example, the absorption section 520 may include ten to twenty quantum well layers, in various embodiments.

In various embodiments, the EML 500 comprises a laser cavity 511 that extends from a first end 512A to a second end 512B. The optical gain section 510 is disposed within the laser cavity 511. In various embodiments, the laser cavity 511 has a cavity length L measured parallel to a longitudinal axis of the EML. In various embodiments, the cavity length L is less than 100 microns. In certain embodiments, the cavity length L is forty microns or less (e.g., 20-35 microns).

The first end 512A of the optical cavity 511 is defined by a first Bragg grating 514A. The first Bragg grating 514A is disposed between the optical gain section 510 and the absorption section 520. In an example embodiment, the first Bragg grating 514A is a Bragg reflector or high-contrast grating. The second end 512B of the optical cavity 511 is disposed longitudinally on an opposite side of the optical gain section 510 of the first Bragg grating 514A. For the EML 500, the second end 512B is defined by a second Bragg grating 514B. In various embodiments, the reflectivity of the second Bragg grating 514B is greater than the reflectivity of the first Bragg grating 514A. For example, a Bragg grating comprises periodic alternating regions of characterized by different refractive indices. In various embodiments, the second Bragg grating 514B may include a larger number of periodic alternating regions than the first Bragg grating 514A.

In various embodiments, the EML 500 is configured to emit light and/or a modulated optical signal along the longitudinal axis of the EML 500. For example, the optical gain section 510 is driven and/or has DC current inserted therein via a laser electrode 552. For example, a laser driving signal may be provided to the laser pad 554. The laser driving current may then be provided to the laser electrode 552 via an electrically conductive path provided between laser pad 554 and the laser electrode 552. As a result of photon generation within the laser cavity 511 caused by driving of the optical gain section 510, a DC optical signal is emitted from the laser cavity 511 via the first Bragg grating 514A.

The optical signal is modulated via the modulator 521 comprising the absorption section 520 to provide a modulated optical signal. For example, the modulator 521 may be driven by a modulator driving RF signal via a modulator electrode 562. For example, a modulator driving signal may be provided to a modulator pad 564. The modulator driving signal may then be provided to the modulator electrode 562 via an electrically conductive path provided between the modulator pad 564 and the modulator electrode 562. In various embodiments, the modulator 521 is driven by a differential signal. For example, the modulator driving signal may be a differential radio frequency (RF) electrical signal.

In various embodiments, the modulator 521 comprises an integrated resistive heater 570 disposed proximate the absorption section 520. For example, the heater 570 is configured to be in thermal communication with the absorption section. For example, heater 570 is in thermal communication with the quantum well layers of the absorption section 520. In certain embodiments, heater 570 is operable to maintain the quantum well layers of the absorption section 520 at a substantially constant temperature corresponding to an operating ambient temperature range value. The heater is activated when an ambient temperature of an environment about the EML 500 falls below the maximum ambient temperature value (Tmax, which is generally in a range of 70-90 C, for example approximately 80 C). For example, when the ambient temperature of the environment around the EML 500 is at least the constant operating temperature value, the heater 570 may not be operated to impart heat to the absorption section 520. However, when the ambient temperature of the environment around the EML 500 is less than the constant operating temperature value, the heater 570 is operated to maintain the absorption section 520 at the constant operating temperature value. For example, the absorption section 520 may be configured to absorb photons more efficiently when at a temperature of the constant operating temperature value (compared to when the absorption section 520 is at a temperature that is less than the operating temperature value). For example, operation of the heater 570 may be configured to reduce the voltage swing of the modulator driver signal required for the modulator 521 (compared to if the heater 570 were not present) to provide an appropriate extinction ratio.

In various embodiments, the heater 570 is operated by causing a current to flow therethrough. For example, a current may be provided to a first heater pad 572A. The current flows from the first heater pad 572A through the resistive heater 570 causing heat to be generated. The second heater pad 572B may be electrically coupled to ground.

In some embodiments, heat isolation trenches 580A, 580B may be etched along the lateral sides of the absorption section 520 and the heater 570. For example, the heat isolation trenches 580A, 580B may act to reduce conduction of heat generated by the heater 570 to other portions of the EML chip including the =laser 511.

While various combinations of EML features are illustrated by FIGS. 1-5, it should be understood that various other combinations of EML features are provided by various embodiments. For example, in certain embodiments, an EML comprises a laser cavity defined at a first end by a first Bragg grating and defined at a second end by a mirror (e.g., a cleaved mirror) and having a modulator comprising a segmented absorption section and/or configured as a TW-EAM. In another example, an EML may comprise a laser cavity comprising or being laterally coupled to a distributed feedback grating and having a modulator comprising an integrated resistive heater. In another example, an EML may comprise a modulator comprising a segmented absorption section and/or configured as a TW-EAM and the modulator includes an integrated resistive heater.

In various embodiments, the single optical mode operation of the laser of the EML is ensured by a phase-shifted DFB grating (e.g., DFB grating 319, 419) disposed in the laser cavity or laterally coupled to the optical mode propagating inside the waveguide ridge. For example, the DFB grating may include a ¼ wavelength phase shift so as to ensure single optical mode operation of the laser of the EML.

In some embodiments, the single optical mode operation of the laser of the EML is ensured by controlling the stop band of the first Bragg grating (e.g., a front mirror/reflector defining one longitudinal end of the laser cavity) and the second Bragg grating (e.g., a back mirror/reflector defining an opposite longitudinal end of the laser cavity) and/or a DFB grating. The overlap of the stop bands may be configured to be narrower than the cavity mode spacing such that only one optical mode of the cavity is able to be within the overlap of the stop bands.

For example, for the EML 200, the first Bragg grating 214A defines a first stop band and the second Bragg grating 214B defines a second stop band. In another example, for the EMLs 300, 400, the first Bragg grating 314, 414A defines a first stop band and the DFB grating 319, 419 may define a feedback stop band. The overlap of the first stop band and the second stop band or the feedback stop band is configured such that a single cavity mode is able to be present within the overlap. In an example embodiment, the second stop band defined by the second Bragg grating 414B may be approximately the same as the first stop band defined by the first Bragg grating 414A or the feedback stop band defined by the DFB grating 419.

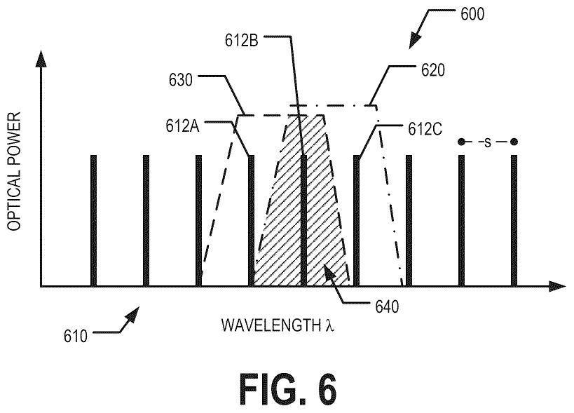

FIG. 6 illustrates a plot 600 that illustrates an array of cavity modes 610 comprising a plurality of cavity modes (e.g., 612A, 612B, 612C) that are separated from one another by a cavity mode spacing s. The first stop band 620 includes multiple cavity modes (e.g., cavity modes 612B, 612C) as the first stop band 620 is wider than the cavity mode spacing s. The second stop band or feedback stop band 630 also includes multiple cavity modes (e.g., cavity modes 612A, 612C) as the second stop band or feedback stop band 630 is wider than the cavity mode spacing s. The first top band 620 and the second stop band or feedback stop band 630 are offset from one another by a fraction of respective widths of the first stop band and the second stop band or feedback stop band. The overlap in the first stop band 620 and the second stop band or feedback stop band 630 defines a wavelength overlap region 640 and a width of the wavelength overlap region 640 is smaller than the respective widths of the first stop band 620 and the second stop band or the feedback stop band 630. The width of the wavelength overlap region 640 is smaller than or comparable to the mode spacing s of the laser cavity to cause the EML laser to operate in a single longitudinal optical mode.

The combined stop band is the wavelength overlap region 640 where the first stop band 620 and the second stop band or feedback stop band 630 overlap. As the laser current is increased from zero, the carrier concentration within the optical gain section is rising, and the cavity modes 612 are swept from right to the left, until a cavity mode reaches the combined stop band (e.g., wavelength overlap region 640) and threshold gain is obtained. At higher currents (above the threshold current Iₜₕ) the carrier concentration is clamped, and the cavity modes do not move by much. Thus, the EML can be operated to provide a consistent, single optical mode output.

### Example EML Mounted to a Silicon Photonics Carrier

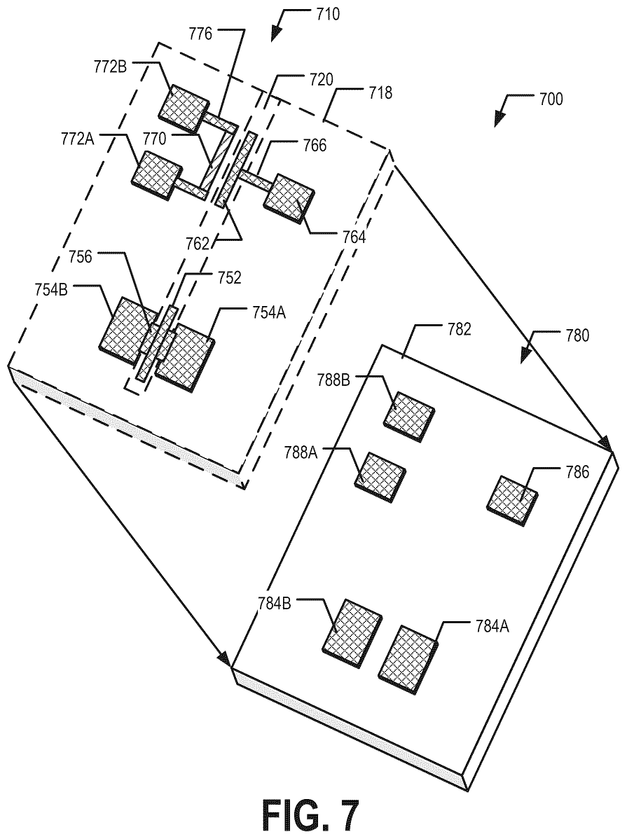

In various embodiments, an EML is formed and/or disposed on a substrate. For example, the substrate may be a GaAs substrate when the EML is a GaAs-based short cavity EML. The EML may be configured to be mounted to a silicon photonics carrier or chip. In some embodiments, the EML may be configured to be flip-chip bonded to a silicon photonics carrier or chip. For example, FIG. 7 provides an exploded view of a mounted EML 700 that includes an EML chip 710 that is flip-chip mounted to a silicon photonics carrier 780.

The EML chip 710 includes a substrate 718 having an EML 720 formed thereon. Laser pads 754A, 754B are disposed on the substrate 718 and configured to provide current to the optical gain section of the EML 720 via laser electrode 752. Modulator pad 764 is disposed on the substrate 718 and configured to provide a modulator driving signal to the absorption section of the EML 720 via modulator electrode 762. Heater pads 772A, 772B are disposed on the substrate 718 and configured to provide current to the integrated resistive heater 770 which is in thermal communication with the modulator of the EML 720.

The silicon photonics carrier 780 includes a silicon photonics chip 782, which may contain silicon based electronic circuitry. Laser bonding pads 784A, 784B are disposed on the silicon photonics chip 782 and are configured for having the laser pads 754A, 754B bonded thereto. For example, the laser bonding pads 784A, 784B are configured to provide a current to the laser pads 754A, 754B. A modulator bonding pad 786 is also disposed on the silicon photonics chip 782. The modulator bonding pad 786 is configured to have the modulator pad 764 bonded thereto. The modulator bonding pad 786 is configured to provide a driving signal to the modulator pad 764 for controlling operation of the modulator of the EML 720. Heater bonding pads 788A, 788B are also disposed on the silicon photonics chip 782. The heater bonding pads 788A, 788B are configured to have the heater pads 772A, 772B bonded thereto. The heater bonding pads 788A, 788B are configured to provide a current to the heater pads 772A, 772B for controlling operation of the heater 770.

The laser pads 754A, 754B, laser contact traces 756, and laser bonding pads 784A, 784B are configured to create a high thermal conductivity path from the optical gain section of the EML 720 to a silicon photonic substrate heat sink of the silicon photonics chip 782. The modulator pad 764, modulator trace 766, and modulator bonding pad 786 and the heater pads 772A, 772B, heater contact traces 776, and heater bonding pads 788A, 788B are configured to create a low thermal conductivity path from the integrated resistive heater 770 and modulator of the EML 720 to the silicon photonic substrate heat sink of the silicon photonics chip 782. In this context, the terms low and high refer to the thermal path from the optical gain section of the EML 720 to the silicon photonic substrate heat sink of the silicon photonics chip 782 having a higher thermal conductivity than the thermal path from the heater 770 and/or the modulator of the EML 720 to the silicon photonic substrate heat sink of the silicon photonics chip 782. In other words, the thermal path from the heater 770 and/or the modulator of the EML 720 to the silicon photonic substrate heat sink of the silicon photonics chip 782 has a lower thermal conductivity than the thermal path from optical gain section of the EML 720 to the silicon photonic substrate heat sink of the silicon photonics chip 782.

The EML chip 710 is configured such that the laser pads 754A, 754B are located near the optical gain section of the EML 720. For example, the laser pads 754A, 754B are in electrical communication with the laser electrode 752 via short, wide laser contact traces 756 or electrical contacts (e.g., shorter and wider than the modulator trace 766 and/or heater contact traces 776). This creates a high thermal conductivity path from the optical gain section of the EML 720 to the substrate heat sink of the silicon photonics chip 782. On the other hand, the modulator trace 766 electrically connecting the modulator pad 764 to the modulator electrode 762 and heater contact traces 776 electrically connecting the heater pads 772A, 772B to the heater 770 are narrow and the pads are located further away. For example, the modulator trace 766 and the heater contact traces 776 are longer and narrower than the laser contact traces 756. Thus, the thermal path from the heater 770 and the modulator of the EML 720 to the substrate heat sink of the silicon photonics chip 782 is a low thermal conductivity path (e.g., has lower thermal conductivity than the thermal path from the optical gain section of the EML 720 to the substrate heat sink of the silicon photonics chip 782). This configuration can obtain high heater power efficiency, without significantly degrading the laser performance due to unwanted heating.

### Example Array of EMLs and Example WDM Sources

In various embodiments, a plurality of EMLs (e.g., EMLs 100, 200, 300, 400, 500) may be incorporated into an array of EMLs. In some embodiments, the array of EMLs is configured as a monolithic wavelength division multiplexing (WDM) array. For example, the array of EMLs may be configured as a WDM source configured for performing coarse WDM or dense WDM. In such embodiments, each EML of the array of EMLs is configured to emit at a different wavelength. Control over the different wavelengths of the EMLs of the array of EMLs can be achieved by E-Beam lithography changing the periods of the gratings that are used for each laser cavity. Optionally, the gain spectral position of the lasers and EAMs of the EMLs of the array can also be slightly adjusted by selective area growth techniques (SAG).

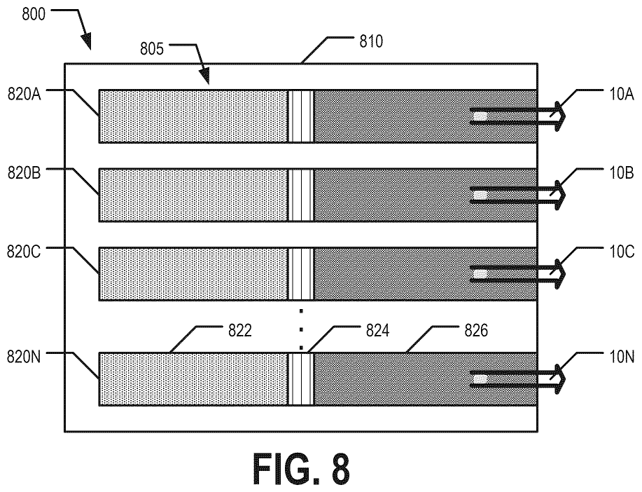

FIG. 8 illustrates an array 800 of EMLs. The array 800 comprises a plurality of EMLs 820A, 820B, 820C, . . . , 820N that are configured as a WDM array 805. In various embodiments, a WDM source is configured for performing coarse WDM (CWDM) or dense WDM (DWDM). For example, a WDM source is configured to generate a plurality of spectral lines (each characterized by a different wavelength) that may independently have a respective data stream encoded thereon. The plurality of spectral lines may be combined to form an optical signal carrying a plurality of data streams.

In the illustrated embodiment, each EML 820A-N of the array 800 includes a respective optical gain section 822, an absorption section 826, and a first Bragg grating 824 disposed between the optical gain section 822 and the absorption section 826. The absorption section 826 includes more quantum well layers than the optical gain section 822. For example, the absorption section 826 may include ten or more quantum well layers. In various embodiments, each of the EMLs 820 may further includes a second Bragg grating and/or DFB grating(s) and one or more of the first Bragg grating, second Bragg grating, and/or DFB grating(s) are configured to cause the EML to operate and/or emit a single optical mode (e.g., a single spectral line).

In various embodiments, each of the EMLs 820 emits a modulated spectral line and/or (approximately) single wavelength optical signal 10A, 10B, 10C, . . . , 10N characterized by a respective wavelength. In various embodiments, EMLs 820 are configured such that each of the EMLs 820 emits a modulated spectral line and/or (approximately) single wavelength optical signal 10A-N that is unique within the array 800. For example, a first EML 820A emits a first modulated spectral line and/or (approximately) single wavelength optical signal 10A characterized by a first wavelength λ_{A}, a second device 820B emits a second modulated spectral line and/or (approximately) single wavelength optical signal 10B characterized by a second wavelength λ_{B}, a third EML 820C emits a third modulated spectral line and/or (approximately) single wavelength optical signal 10C characterized by a third wavelength λ_{C}, and a Nth EML 820N emits an Nth modulated spectral line and/or (approximately) single wavelength optical signal 10N characterized by an Nth wavelength λ_{N}. The EMLs 820A-N =are configured such that the first wavelength λ_{A} is different from each of the second, third, . . . , and Nth wavelengths λ_{B}-λ_{N}. For example, λ_{A}≠λ_{B}≠λ_{C}≠ . . . ≠λ_{N}. For example, the first Bragg gratings of the plurality of EMLs 820 may have different periods such that each EML 820 of the array 800 is configured to produce a different wavelength than other EMLs of the array 800.

In an example embodiment, the EMLs 820 are configured such that the k^{th} wavelength of the plurality of wavelengths λ_{A}-λ_{N} is given as λ_{A}+kΔλ, where Δλ is a wavelength step between adjacent spectral lines of the WDM array 805. In various embodiments, the WDM array 805 is configured to perform coarse or dense WDM.

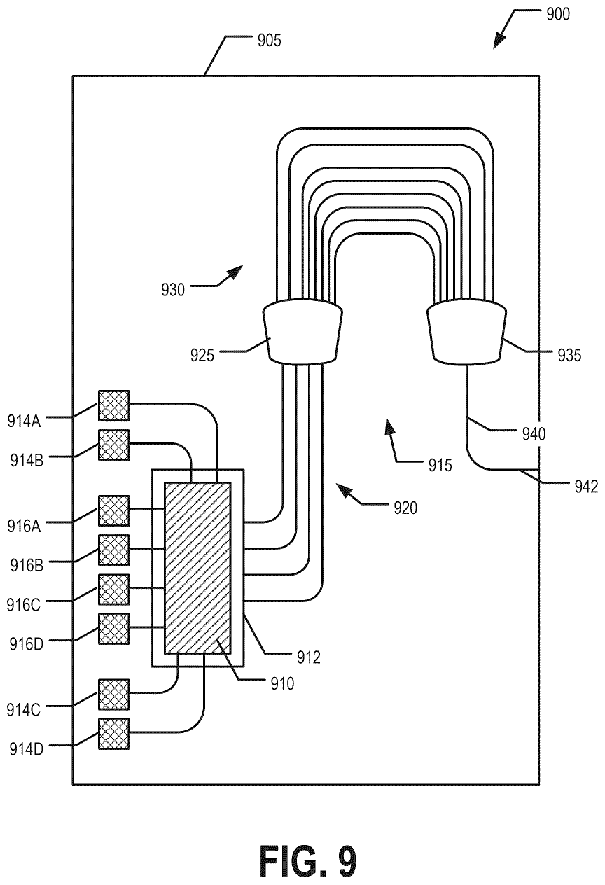

In various embodiments, an array of EMLs, which may be configured as a WDM source, is coupled directly to a planar silicon photonics wavelength multiplexer. For example, FIG. 9 illustrates a WDM source 900 comprising an EML array chip 912 having a WDM array 910 of short cavity (GaAs-based) EMLs disposed thereon. The EML array chip 912 is flip-chip bonded to a silicon photonics chip 905. The laser pads of the EML array chip 912 are electrically coupled to respective laser bonding pads 916 (e.g., 916A, 916B, 916C, 916D) of the silicon photonics chip 905 and the modulator pads of the EML array chip 912 are electrically coupled to respective modulator bonding pads 914 (e.g., 914A, 914B, 914C, 914D).

The modulated spectral line emitted by each EML of the WDM array 910 is provided to respective waveguide of a series of waveguides 920 of the silicon photonics chip 905. The series of waveguides 920 provides the modulated spectral lines to the silicon photonics array waveguide (AWG) WDM combiner 915. The silicon photonics AWG WDM combiner 915 includes an input star coupler 925, a waveguide array 930, an output star coupler 935, and an output waveguide 940. The output waveguide 940 provides a multi-wavelength optical signal including each of the modulated spectral lines generated by the WDM array 910. The output waveguide 940 may provide the multi-wavelength optical signal to an optical fiber via coupler 942.

For example, as shown in FIG. 9, the edge emitting WDM array 910 can be coupled directly to planar Silicon Photonics (SiP) wavelength multiplexers. For example, the monolithic WDM array 910 is flip-chip bonded into optical communication with a silicon photonic arrayed waveguide grating (AWG) device (e.g., silicon photonics AWG WDM combiner 915) that combines multiple different wavelength EML outputs (e.g., modulated spectral lines characterized by different wavelengths) into a single multi-wavelength optical signal provided as output. Some advantages of such a configuration include the potentially simple alignment process required for a single chip bonding, and the better heat spreading properties associated with flip-chip bonding on silicon.

### Example Optical Interconnect Including an Array of EMLs

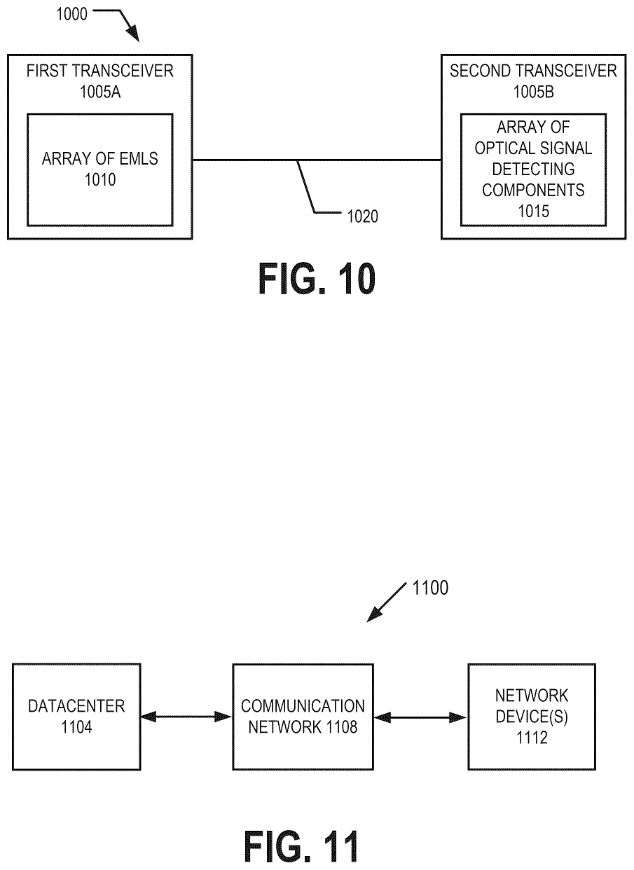

FIG. 10 illustrates an example optical interconnect 1000 including one or more EMLs of various embodiments. For example, an optical interconnect 1000 may include an array of EMLs, possibly configured as a WDM array and/or as part of a WDM source.

The optical interconnect 1000 comprises a first transceiver 1005A and a second transceiver 1005B. The first transceiver 1005A is in optical communication with the second transceiver 1005B via one or more optical fibers 1020. The first transceiver 1005A comprises an array of EMLs 1010. For example, the array of EMLs may be configured as a WDM array 805 and/or incorporated into a WDM source 900. In various embodiments, the array of EMLs 1010 are configured to generate a plurality of spectral lines (e.g., with one spectral line generated by each EML of the array). In an example embodiment, each spectral line may be modulated such that a respective digital data stream is encoded therein.

The second transceiver 1005B comprises an array of optical signal detecting components 1015. In various embodiments, the array of optical signal detecting components 1015 is an array of photodiodes, photodetectors, and/or other optical signal detecting devices. In various embodiments, the optical signal detecting components of the array of optical signal detecting components 1015 are configured to receive respective optical signals via optical filters.

For example, the first transceiver 1005A comprises a WDM source configured to generate a plurality of spectral lines that are modulated to provide a WDM optical signal having, possibly, multiple channels of data encoded therein. The WDM optical signal is then provided to the second transceiver 1005B via the optical fiber 1020, for example. One or more optical signal detecting components that may include respective photodiodes and/or other photodetectors may receive and/or detect respective portions of the optical signal (e.g., corresponding to respective spectral lines) such that information is communicated from the first transceiver 1005A to the second transceiver 1005B via the optical signal(s).

### Example Datacenter

In various embodiments, a system includes EMLs (e.g., EMLs 100, 200, 300, 400, 500), in accordance with various embodiments. For example, a WDM source comprising a plurality of EMLs (e.g., WDM source 900 or another WDM source comprising a WDM array 805) may be used as a coarse or dense WDM optical source of a transceiver of an optical link. For example, as shown in FIG. 10, WDM sources comprising EMLs of various embodiments may be incorporated into an optical interconnect. Such an optical interconnect may be part of a datacenter.

For example, an optical interconnect comprising EMLs of various embodiments may be used to place various components of a datacenter in communication with one another. In various embodiments, the system may include a pluggable optical interconnect, a chip-to-chip, board-to-board, intra rack servers, rack-to-rack optical interconnect, an optical network comprising a plurality of optical interconnect, dense Wavelength Division Multiplexing (WDM) optical links, WDM or DWDM source and/or the like that includes one or more WDM sources comprising one or more EMLs of various embodiments as well as for AI fabrics and full range of different kinds of automative vehicles. For example, a WDM source may be configured to generate optical signals that are transmitted along one or more optical communication paths between two components of a datacenter, in accordance with an example embodiment.

Datacenters may include multiple network switches in a particular topology, such as a fat tree topology, a slim fly topology, a dragonfly topology, and/or the like. The specifications and makeup of the network switches in the topology affects the overall network performance (e.g., bandwidth capability) of the datacenter.

Datacenters are the storage and data processing hubs of the internet. The massive deployment of cloud applications is causing datacenters to expand exponentially in size, stimulating the development of faster switches than can cope with the increasing data traffic inside the datacenter. Current state-of-the-art switches are capable of handling 12.8 Tb/s of traffic by employing electrical switches in the form of application specific integrated circuits (ASICs) equipped with 256 data lanes, each operating at 50 Gbps. Such switching ASICs typically consume as much as 400 W, and the power consumption of the optical transceiver interfaces attached to each ASIC is comparable. To keep pace with traffic demand, switch capacity doubles approximately every two years. To date, this rapid scaling has been made possible by exploiting advances in manufacturing (e.g., CMOS techniques), collectively described by Moore's law (i.e., the observation that the number of transistors in a dense integrated circuit doubles about every two years). However, in recent years there are strong indications of Moore's law slowing down, which raises concerns about the capability to sustain the target scaling rate of switch capacity. As a result, alternative technologies are being investigated.

FIG. 11 illustrates a system 1100 according to at least one example embodiment. The system 1100 includes a datacenter 1104, a communication network 1108, and one or more network devices 1112. In at least one example embodiment, the datacenter 1104 corresponds to a collection of network devices, such as network switches (e.g., Ethernet switches) connected with a collection of servers or compute nodes. The datacenter 1104 may adhere to a networking topology (e.g., a hierarchal networking topology), such as a fat tree topology, a Slim Fly topology, a Dragonfly topology, and/or the like. The datacenter 1104 routes traffic amongst the network switches and servers therein, and at least one layer of the topology in the datacenter 1104 is coupled to the communication network 1108 to allow networking traffic to flow between the datacenter 1104 and the network device(s) 1112.

Examples of the communication network 1108 that may be used to connect the datacenter 1104 and the network device(s) 1112 include an Internet Protocol (IP) network, an Ethernet network, an InfiniBand (TB) network, a Fibre Channel network, the Internet, a cellular communication network, a wireless communication network, combinations thereof (e.g., Fibre Channel over Ethernet), variants thereof, and/or the like.

The one or more network devices 1112 may include switch, router, or Network Interface Controller (NIC), interconnect using ports, one or more of Personal Computer (PC), a laptop, a tablet, a smartphone, a server, a collection of servers, and/or any suitable computing device for sending and receiving signals over the communication network 1108. In at least one example embodiment, the one or more network devices 1112 correspond to another datacenter, similar to or the same as datacenter 1104.

As noted above, the datacenter 1104 and/or the network device(s) 1112 may include storage devices and/or processing circuitry for carrying out computing tasks, for example, tasks associated with controlling the flow of data internally and/or over the communication network 1108. Such processing circuitry may comprise software, hardware, or a combination thereof. For example, the processing circuitry may include a memory including executable instructions and a processor (e.g., a microprocessor) that executes the instructions on the memory. The memory may correspond to any suitable type of memory device or collection of memory devices configured to store instructions. Non-limiting examples of suitable memory devices that may be used include Flash memory, Random Access Memory (RAM), Read Only Memory (ROM), variants thereof, combinations thereof, or the like. In some embodiments, the memory and processor may be integrated into a common device (e.g., a microprocessor may include integrated memory).

Additionally or alternatively, the processing circuitry may comprise hardware, such as an application specific integrated circuit (ASIC). For example, the processor may be or include one or more of an Integrated Circuit (IC) chip, a microprocessor, a Central Processing Unit (CPU), a Graphics Processing Unit (GPU), a Data Processing Unit (DPU), a Field Programmable Gate Array (FPGA), a network interface controller (NIC), an ASIC, combinations thereof, and the like. The processing circuitry may comprise an ASIC and/or may be capable of performing as a central processing unit (CPU), a graphics processing unit (GPU), a network interface controller (NIC), a data processing unit (DPU), or any other computing device in which with data is received and/or transmitted.

Some or all of the processing circuitry may be provided on a Printed Circuit Board (PCB) or collection of PCBs. It should be appreciated that any appropriate type of electrical component or collection of electrical components may be suitable for inclusion in the processing circuitry.

In addition, although not explicitly shown, it should be appreciated that the datacenter 1104 and network device(s) 1112 may include one or more communication interfaces for facilitating wired and/or wireless communication between one another and other unillustrated elements of the system 1100.

In related art systems, a fat tree topology may use the same electrical switching devices on all layers (edge, aggregation, core). For example, each switching device may be 1 U switch, where 1 U refers to the industry standard size for rack-mounted switch and/or server. The interconnection between switches of different layers may be accomplished with optical links or optical interconnects using active optical cables and optical transceivers implemented in a pluggable form factor (also referred to as “pluggables”).

Optical Datacenter Networks rely on allocation and deallocation of light paths from the data sources to the destinations end-ports to guarantee no light collisions and data loss occur in the fabric. Traditionally the allocation algorithms are run from a central entity which considers the entire demand for source and destination flows and try to find the most dense mapping of these demands to network resources over a single or multiple time periods.

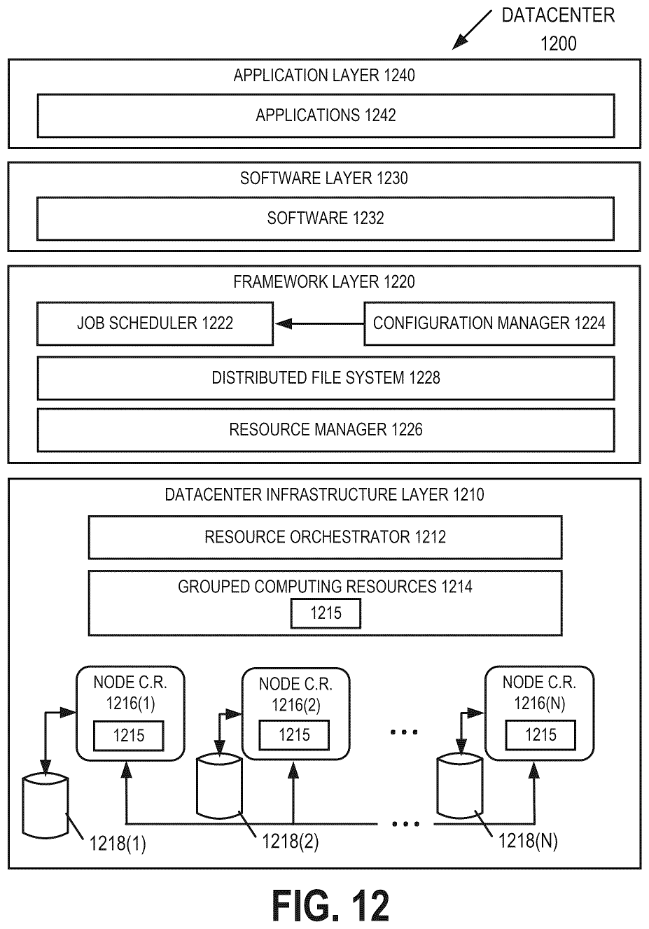

FIG. 12 illustrates an example datacenter 1200, in which at least one embodiment may be used. In at least one embodiment, datacenter 1200 includes a datacenter infrastructure layer 1210, a framework layer 1220, a software layer 1230, and an application layer 1240.

In at least one embodiment, as shown in FIG. 12, datacenter infrastructure layer 1210 may include a resource orchestrator 1212, grouped computing resources 1214, and node computing resources (“node C.R.s”) 1216(1)-1216(N), where “N” represents a positive integer (which may be a different integer “N” than used in other figures). In at least one embodiment, node C.R.s 1216(1)-1216(N) may include, but are not limited to, any number of central processing units (“CPUs”) or other processors (including accelerators, field programmable gate arrays (FPGAs), graphics processors, etc.), memory storage devices 1218(1)-1218(N) (e.g., dynamic read-only memory, solid state storage or disk drives), network input/output (“NW I/O”) devices, network switches, virtual machines (“VMs”), power modules, and cooling modules, etc. In at least one embodiment, one or more node C.R.s from among node C.R.s 1216(1)-1216(N) may be a server having one or more of above-mentioned computing resources.

In at least one embodiment, grouped computing resources 1214 may include separate groupings of node C.R.s housed within one or more racks (not shown), or many racks housed in datacenters at various geographical locations (also not shown). In at least one embodiment, separate groupings of node C.R.s within grouped computing resources 1214 may include grouped compute, network, memory, or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 1212 may configure or otherwise control one or more node C.R.s 1216(1)-1216(N) and/or grouped computing resources 1214. In at least one embodiment, resource orchestrator 1212 may include a software design infrastructure (“SDI”) management entity for datacenter 1200. In at least one embodiment, resource orchestrator 1212 may include hardware, software or some combination thereof.

In at least one embodiment, as shown in FIG. 12, framework layer 1220 includes a job scheduler 1222, a configuration manager 1224, a resource manager 1226 and a distributed file system 1228. In at least one embodiment, framework layer 1220 may include a framework to support software 1232 of software layer 1230 and/or one or more application(s) 1242 of application layer 1240. In at least one embodiment, software 1232 or application(s) 1242 may respectively include web-based service software or applications, such as those provided by Amazon Web Services, Google Cloud and Microsoft Azure. In at least one embodiment, framework layer 1220 may be, but is not limited to, a type of free and open-source software web application framework such as Apache Spark™ (hereinafter “Spark”) that may utilize distributed file system 1228 for large-scale data processing (e.g., “big data”). In at least one embodiment, job scheduler 1222 may include a Spark driver to facilitate scheduling of workloads supported by various layers of datacenter 1200. In at least one embodiment, configuration manager 1224 may be capable of configuring different layers such as software layer 1230 and framework layer 1220 including Spark and distributed file system 1228 for supporting large-scale data processing. In at least one embodiment, resource manager 1226 may be capable of managing clustered or grouped computing resources mapped to or allocated for support of distributed file system 1228 and job scheduler 1222. In at least one embodiment, clustered or grouped computing resources may include grouped computing resources 1214 at datacenter infrastructure layer 1210. In at least one embodiment, resource manager 1226 may coordinate with resource orchestrator 1212 to manage these mapped or allocated computing resources.

In at least one embodiment, software 1232 included in software layer 1230 may include software used by at least portions of node C.R.s 1216(1)-1216(N), grouped computing resources 1214, and/or distributed file system 1228 of framework layer 1220. In at least one embodiment, one or more types of software may include, but are not limited to, Internet web page search software, e-mail virus scan software, database software, and streaming video content software.

In at least one embodiment, application(s) 1242 included in application layer 1240 may include one or more types of applications used by at least portions of node C.R.s 1216(1)-1216(N), grouped computing resources 1214, and/or distributed file system 1228 of framework layer 1220. In at least one embodiment, one or more types of applications may include, but are not limited to, any number of a genomics application, a cognitive compute, application and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 1224, resource manager 1226, and resource orchestrator 1212 may implement any number and type of self-modifying actions based on any amount and type of data acquired in any technically feasible fashion. In at least one embodiment, self-modifying actions may relieve a datacenter operator of datacenter 1200 from making possibly bad configuration decisions and possibly avoiding underutilized and/or poor performing portions of a datacenter.

In at least one embodiment, datacenter 1200 may include tools, services, software, or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to datacenter 1200. In at least one embodiment, trained machine learning models corresponding to one or more neural networks may be used to infer or predict information using resources described above with respect to datacenter 1200 by using weight parameters calculated through one or more training techniques described herein.

In at least one embodiment, datacenter may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 1215 are used to perform inferencing and/or training operations associated with one or more embodiments. In at least one embodiment, inference, and/or training logic 1215 may be used in system FIG. 12 for inferencing or predicting operations based, at least in part, on weight parameters calculated using neural network training operations, neural network functions and/or architectures, or neural network use cases described herein.

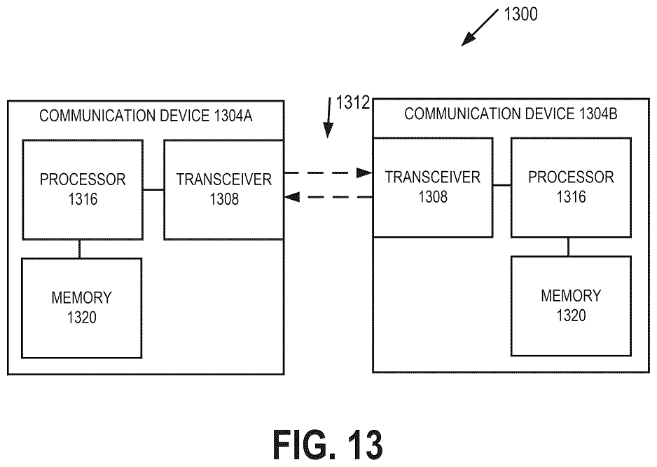

FIG. 13 illustrates a system 1300 including a first communication device 1304A and a second communication device 1304B. Illustratively, but without limitation, the communication devices 1304 (e.g., 1304A, 1304B) may correspond to network devices (e.g., network devices 812). As such, the communication devices 1304 may correspond to any type of device that becomes part of or is connected with a communication network (e.g., communication network 808). Examples of suitable devices that may act or operate like a communication device 1304 as described herein include, without limitation, one or more of a Personal Computer (PC), a laptop, a tablet, a smartphone, a server, a collection of servers, a networking card, an edge router, a switch, Network Interface Controller, a Top of Rack (ToR) switch, a server blade, or the like. The communication device 1304 may include a transceiver 1308, a processor 1316, and memory 1320. The transceiver 1308 may include hardware that enables communications over the communication channel 1312 whereas the processor 1316 and memory 1320 may include components that enable the communication device 1304 to provide a desired functionality or perform certain functions.

The communication channel 1312 may traverse a datacenter or any type of communication network (whether trusted or untrusted). Examples of a communication network that may be used to connect communication devices 1304 and support the communication channel 1312 include, without limitation, an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like. In one specific, but non-limiting example, the communication network enables data transmission between the communication devices 1304 using optical signals. In this case, the communication devices 1304 and the communication network may include waveguides (e.g., optical fibers) that carry the optical signals. For example, the communication devices and/or the communication network may include one or more WDM sources comprising short cavity GaAs-based EMLs of various embodiments, according to various embodiments.

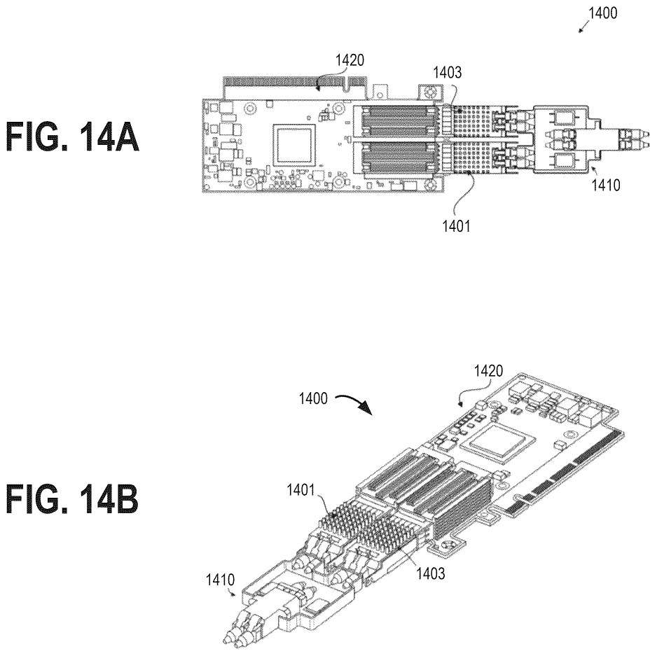

FIGS. 14A and 14B illustrate a top view and a perspective view, respectively, of a transceiver module operatively coupled to a network adapter, in the present example a Network Interface Controller (NIC) 1400, in accordance with an embodiment of the disclosure. As shown in FIGS. 14A and 14B, the transceiver module may include a first optical module 1401, a second optical module 1403, an adapter 1410, and a dual-port NIC 1420 of a server. Both the first optical module 1401 and the second optical module 1403 may be dual-fiber transceivers that are configured for duplex communication that allows the source (e.g., server) to communicate with the target (e.g., leaf switch) in both directions. The adapter 1410 may be a ganged physical component configured to link the first optical module 1401 and the second optical module 1403 for the purpose of transmitting and receiving data to and from the leaf switch.

In some embodiments, the adapter 1410 may be configured to operate in two configurations, such as a first configuration and a second configuration. In one aspect, the first configuration may be a default configuration of operation, where the first optical module 1401 may be operationally active. The second configuration may be a contingent configuration that is implemented when the first optical module 1401 operationally fails. When such a failure is detected, the second optical module 1403, which is otherwise operationally inactive or idle, may be engaged become operationally active and handle all network traffic that was initially handled by the first optical module 1401.

In some embodiments, the transceiver module 1400 may be configured to operate in a leaf-spine architecture. A leaf-spine architecture is a data center network topology that may include two switching layers—a spine layer and a leaf layer. The leaf layer may include access switches (leaf switches) that aggregate traffic from servers and connect directly into the spine or network core. Spine switches interconnect all leaf switches in a full-mesh topology between access switches in the leaf layer and the servers from which the access switches aggregate traffic. As such, in one embodiment, to ensure reliable operation of downlinks, the transceiver module 1400 may be configured to operate between the server and the leaf layer. In particular, as shown in FIGS. 14A and 14B, the adapter 1410 may be operatively coupled to the first optical module 1401 and the second optical module 1403, while the first optical module 1401 and the second optical module 1403 may be operatively coupled to a dual-port NIC 1420 of a server.

In embodiments, NIC 1400 may comprise one or more processing circuits, as detailed above; the processing circuits may comprise FW, that is loaded according to the techniques described above.

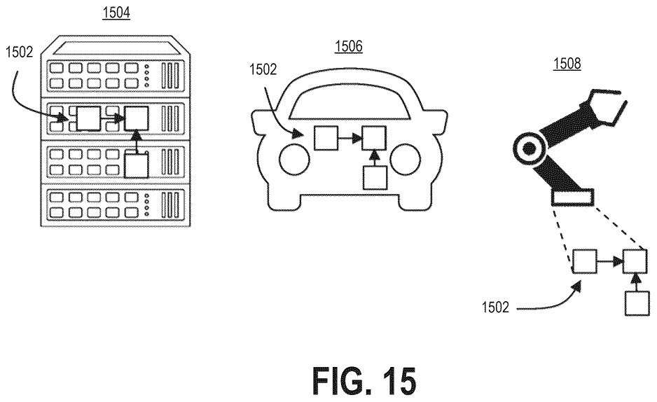

FIG. 15 depicts some exemplary scenarios for use of an optical transceiver 1502 in accordance with some embodiments. An optical transceiver 1502 may be utilized in a computing system 1504 (e.g., in a server farm, or within a server computer system), a vehicle 1506 (e.g., a car, truck, train, or airplane), and a robot 1508 (or among robots in a factory), to name just a few examples. The optical transceiver 1502 may be particularly useful for high-speed communication in environments subject to high levels of electromagnetic interference (EMI).

### Example System Use Case

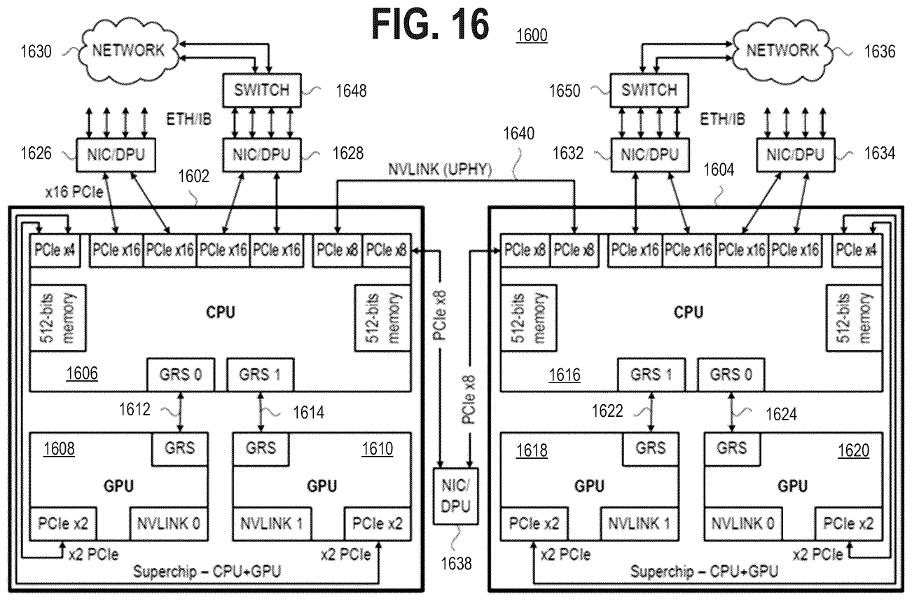

FIG. 16 is a block diagram that schematically illustrates a computing system 1600, e.g., a data center or a High-Performance Computing (HPC) cluster, in accordance with an embodiment that is described herein. System 1600 comprises a plurality of subsystems, e.g., multiple processing devices coupled to each other, multiple network devices, and multiple networks, according to at least one embodiment. Computing system 1600 is designed with multiple integrated circuits (referred to as processing devices), where each integrated circuit can include one or more CPUs and GPUs, forming a powerful and flexible architecture.

The various processing devices are interconnected via an NVLink or other high-speed interconnect, enabling high-speed communication between the subsystems, and are also connected through a NIC or DPU to ensure efficient data transfer across computing system 1600 and to one or more external networks 1630, 1636. In the present example, system 1600 comprises a packet switch 1648 that connects NIC/DPU 1628 to network 1630, and a packet switch 1650 that connects NIC/DPU 1632 to network 1636.

The coupling of processing devices through NVLink allows for seamless data exchange and parallel processing, enhancing overall computational performance. The processing devices are connected to multiple networks through one or more network interface controllers (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 1600 can include one or more CPUs and one or more GPUs.

FIG. 16 also demonstrates an example architecture of a multi-GPU architecture. As illustrated in the figure, computing system 1600 includes a processing device 1602 with a multi-GPU architecture. In particular, processing device 1602 may be a system-on-chip and includes multiple subsystems such as a CPU 1606, a GPU 1608, and a GPU 1610. CPU 1606 can be coupled to GPU 1608 via a die-to-die (D2D) or chip-to-chip (C2C) interconnect 1612, such as a Ground-Referenced Signaling interconnect (GRS interconnect). CPU 1606 can be coupled to GPU 1610 via a D2D or C2C interconnect 1614. CPU 1606 can also couple to GPU 1608 and GPU 1610 via PCIe interconnects. CPU 1606 can be coupled to one or more NICs or DPUs, which are coupled to one or more networks. For example, as illustrated in FIG. 3, CPU 1606 is coupled to a first NIC/DPU 1626, which is coupled to a network 1630. CPU 1606 is also coupled to a second NIC/DPU 1628, which is coupled to network 1630 via switch 1648. NIC/DPU 1626 and NIC/DPU 1628 can be coupled to network 1630 over Ethernet (ETH), NVLINK or InfiniBand (IB) connections, for example.

Computing system 1600 also includes a processing device 1604 with a multi-GPU architecture. In particular, processing device 1604 includes multiple subsystems including a CPU 1616, a GPU 1618, and a GPU 1620. CPU 1616 can be coupled to GPU 1618 via an D2D or C2C interconnect 1622. CPU 1616 can be coupled to GPU 1620 via a D2D or C2C interconnect 1624. CPU 1616 can also couple to GPU 1618 and GPU 1620 via PCIe interconnects. CPU 1616 can be coupled to one or more NICs or DPUs, which are coupled to one or more networks. For example, as illustrated in FIG. 3, CPU 1616 is coupled to a first NIC/DPU 1632, which is coupled to a network 1636. CPU 1616 is also coupled to a second NIC/DPU 1634, which is coupled to network 1636 via switch 1650. NIC/DPU 1632 and NIC/DPU 1634 can be coupled to network 1636 over Ethernet (ETH), NVLINK or InfiniBand (IB) connections.

In at least one embodiment, processing device 1602 and processing device 1604 can communication with each other via a NIC/DPU 1638, such as over PCIe interconnects. Processing device 1602 and processing device 1604 can also communicate with each other over a high-bandwidth communication interconnects 1640, such as an NVLink interconnect or other high-speed interconnects. The packet switches in FIG. 3 may comprise, for example, Nvidia Quantum-2 switches. The NICs/DPUs in the figure may comprise, for example, Nvidia Bluefield DPUs.

In various embodiments, one or more of the interconnects 1612, 1614, 1622, 1624 may be optical interconnects disclosed herein. Additionally, in various embodiments, switches 1648, 1650 may be in communication with NIC/DPU 1628, 1632, respectively, via one or more optical interconnects disclosed herein. In some embodiments, NIC/DPU 1626, 1634 may be in communication with one or more additional elements via optical interconnects disclosed herein. For example, various elements of the computing system 1600 may be in communication with one another via one or more optical interconnects disclosed herein.

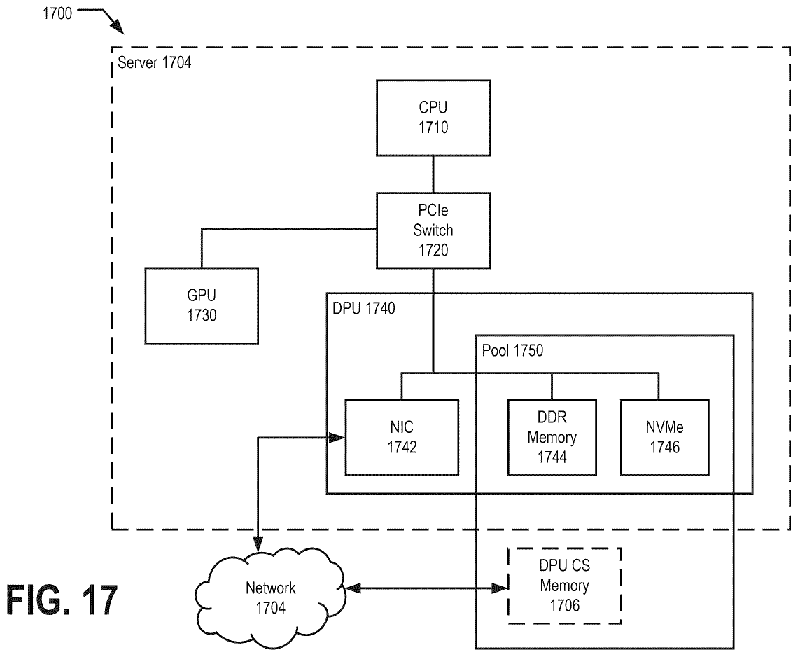

FIG. 17 illustrates an example computing environment 1700 in which forward pass offloading to available memory can be performed, in accordance with at least one embodiment. It should be appreciated that embodiments of the present disclosure may also be used with reference to alternative environments and that specific discussion of components may be provided by way of non-limiting example and may include equivalents. Moreover, various features have been removed for clarity and conciseness. Additionally, systems and methods may be used with a variety of different architectures. The example computing environment 1700 may include a server 1702 which may be used to perform high performance computing (HPC) workloads, such as AI training or machine learning model training. In an embodiment, the server 1702 may be an application instance or a compute node. The server 1702 may include a CPU 1710 associated with a switch 1720, such as a peripheral component interconnect express (PCIe) switch, which may control at least some data transmission over communication paths interconnecting various components. In an embodiment, the CPU 1710 may include a root complex processor.

The PCIe switch 1720 may also be associated with a GPU 1730 and a DPU 1740, and may transmit data between at least some of the CPU 1710, the GPU 1730, the DPU 1740, and other components (e.g., via one or more optical interconnects disclosed herein). In an embodiment, the PCIe switch 1720 may be associated with more than one GPU or more than one DPU. In another embodiment, the PCIe switch 1720 may be located within the DPU 1740. The PCIe switch 1720 may manage the transfer of at least some data between the CPU 1710, the GPU 1730, and the DPU 1740. In another embodiment, the number of GPUs associated with the PCIe switch 1720 may be equal to the number of DPUs associated with the PCIe switch 1720. In at least one embodiment, the server 1702 may include, without limitation, any number of the CPUs 1710, the PCIe switches 1720, the GPUs 1730, and/or the DPUs 1740, in any combination. For example, in at least one embodiment, server 1702 could include eight, sixteen, thirty-two, and/or more GPUs 1730. In at least one embodiment, communication paths interconnecting various components, including but not limited to the CPU 1710, the PCIe switch 1720, the GPU 1730, and the DPU 1740, in FIG. 17 may be implemented using any suitable protocols, such as peripheral component interconnect (PCI) based protocols (e.g., PCIe), or other bus or point-to-point communication interfaces and/or protocol(s), such as NV-Link high-speed interconnect, or interconnect protocols.

The DPU 1740 may include a network interface controller (NIC) 1742, a DDR memory 1744, and a non-volatile memory express (NVMe) device 1746. The NIC 1742 may be able to interface with a network 1704, which may also interface with additional NVMe devices available to the DPU 1740, such as over fabric. In an embodiment, the DPU 1740 may not include the NVMe device 1746. In another embodiment, the NVMe device 1746 may be located on the server 1702 and not on the DPU 1740. In yet another embodiment, the computing environment 1700 may include more than one of the NVMe device 1746, such as a first NVMe device in the DPU 1740 and a second first NVMe device on the server 1702 an associated directly with the PCIe switch 1720. In an embodiment, the DPU 1740 may not include the DDR memory 1744 and may include a computational storage services (CSS) in place of, or in addition to, the DDR memory 1744. For example, computing environment 1700 may include DPU computational storage (CS) memory 1706 available to the DPU 1740 as part of the CSS. The network 1704 may be able to interface with the DPU CS memory 1706 through the NIC 1742, according to any suitable interface protocol, such as remote direct memory access (RDMA) over Ethernet, InfiniBand, Fiber Channel, etc.

The total memory of the computing environment 1700 available for data storage may be expanded through the use of the DPU 1740 on nodes of the system. The DPU 1740 may have access to a pool 1750 of memory already available to the server 1702, such as double data rate (DDR) memory, on-board NVMe devices, NVMe devices over fabric, and CS. The pool 1750 of memory may include at least one of the DDR memory 1744, NVMe 1746, and the DPU CS memory 1706. The DPU 1740 may also be able to access the available memory of other DPUs as part of the pool 1750, and other DPUs may be able to access the available memory of DPU 1740, such as the pool 1750. This available memory can be accessed and utilized for data storage, without the addition of compute resources, such as compute nodes, which would be required using other solutions. The available pool 1750 accessible to the DPU 1740 may be provisioned for the server 1702 to expand the total memory available for data storage, such as to reduce the data storage load on the CPU 1710 or the GPU 1730, which can instead increase the utilization of their memory for processing. For example, during training of an AI, the model states, residual states, activation functions, and checkpoints can be stored, or offloaded, on the pool 1750 accessible to the DPU 1740.

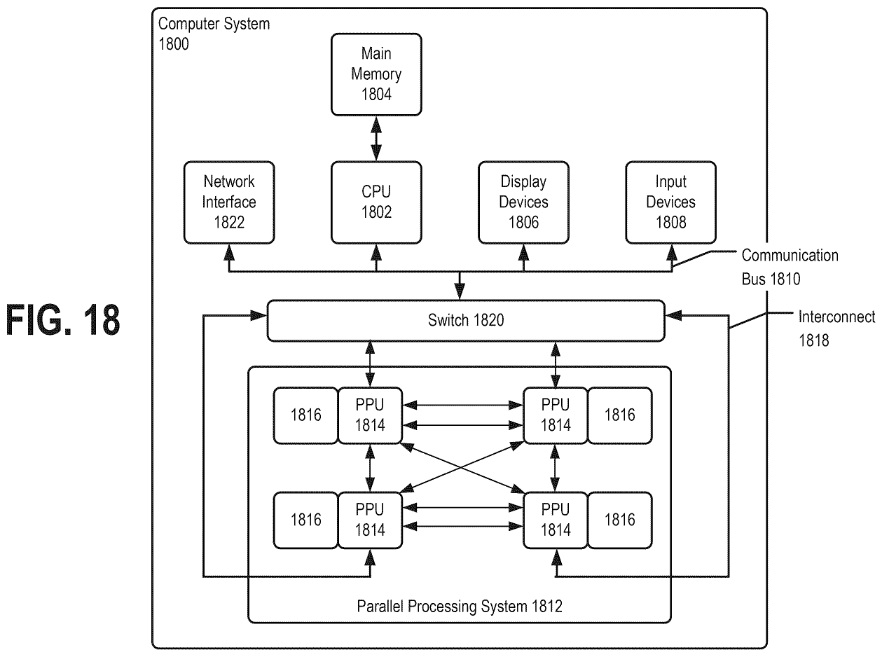

FIG. 18 illustrates a computer system 1800, according to at least one embodiment. In at least one embodiment, computer system 1800 comprises at least one optical interconnect of an example embodiment.

In at least one embodiment, computer system 1800 comprises, without limitation, at least one central processing unit (“CPU”) 1802 that is connected to a communication bus 1810 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 1800 includes, without limitation, a main memory 1804 and control logic (e.g., implemented as hardware, software, or a combination thereof) and data are stored in main memory 1804 which may take form of random access memory (“RAM”). In at least one embodiment, a network interface subsystem (“network interface”) 1822 provides an interface to other computing devices and networks for receiving data from and transmitting data to other systems from computer system 1800.

In at least one embodiment, computer system 1800, in at least one embodiment, includes, without limitation, input devices 1808, parallel processing system 1812, and display devices 1806 which can be implemented using a conventional cathode ray tube (“CRT”), liquid crystal display (“LCD”), light emitting diode (“LED”), plasma display, or other suitable display technologies. In at least one embodiment, user input is received from input devices 1808 such as keyboard, mouse, touchpad, microphone, and more. In at least one embodiment, each of foregoing modules can be situated on a single semiconductor platform to form a processing system.

In at least one embodiment, computer programs in form of machine-readable executable code or computer control logic algorithms are stored in main memory 1804 and/or secondary storage. Computer programs, if executed by one or more processors, enable system 1800 to perform various functions in accordance with at least one embodiment. memory 1804, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 1802; parallel processing system 1812; an integrated circuit capable of at least a portion of capabilities of both CPU 1802; parallel processing system 1812; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 1800 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 1812 includes, without limitation, a plurality of parallel processing units (“PPUs”) 1814 and associated memories 1816. In at least one embodiment, PPUs 1814 are connected to a host processor or other peripheral devices via an interconnect 1818 and a switch 1820 or multiplexer. In at least one embodiment, parallel processing system 1812 distributes computational tasks across PPUs 1814 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 1814, although such shared memory may incur performance penalties relative to use of local memory and registers resident to a PPU 1814. In at least one embodiment, operation of PPUs 1814 is synchronized through use of a command such as_syncthreads( ), wherein all threads in a block (e.g., executed across multiple PPUs 1814) to reach a certain point of execution of code before proceeding.

The PPUs 1814 may be in communication with one another and/or switch 1820 via one or more optical interconnects in accordance with example embodiments disclosed herein.

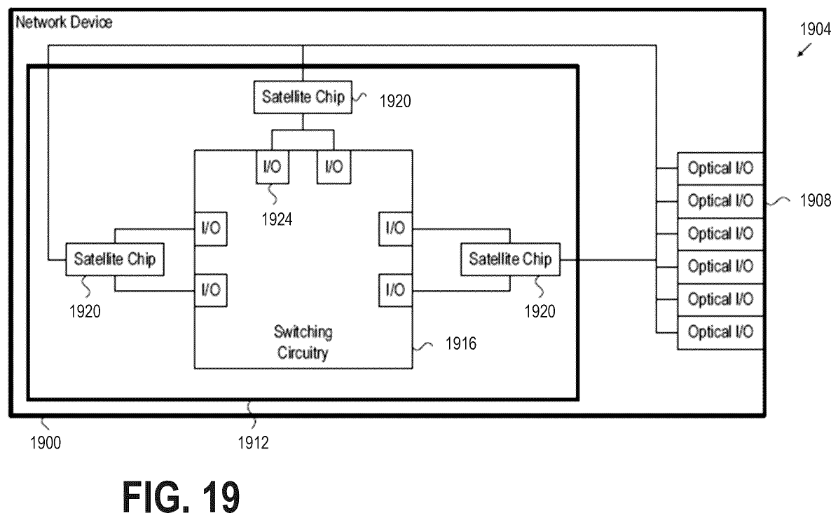

Co-packaging may refer to the close integration of different electrical and/or optoelectronic chips in the same package. FIG. 19 is a block diagram that schematically illustrates a co-packaged Networking Device 1900, in accordance with an embodiment that is disclosed herein. The different chips that constitute a co-packaged Networking Device are assembled on a single substrate in what is typically called the MCM assembly 1912. The MCM assembly 1912 can include a switching circuitry 1916 surrounded by peripheral or satellite chips 1920. In some embodiments, the switching circuitry 1916 and surrounding satellite chips 1920 are all mounted on a common substrate, although such a configuration is not required. The MCM assembly 1912 may be provided in a larger housing of the networking device 1912, positioned behind the front panel 1904. The switching circuitry 1916 may include one or more core digital Application Specific Integrated Circuits (ASICs), CPUs, GPUs, microprocessors, FPGAs, combinations thereof, and the like. The switching circuitry 1916 may include a number of input ports and/or output ports 1928. The Input/Output (I/O) ports 1924 may include electrical ports and/or optical ports. Additionally, the switching circuitry 1916 may include a combination of electrical blocks and optical blocks. The electrical blocks of the switching circuitry 1916 may include a number of electrical switches that are configured to route signals in an electrical domain. The optical blocks of the switching circuitry 1916 may include a number of optical components that are configured to generate, detect, and route signals in an optical domain. The MCM assembly 1912, in some embodiments, may concern or include multiple satellite chips 1920 that are assembled on the same substrate as the switching circuitry 1916. In some embodiments, a configuration of the optical block(s) and a configuration of the electrical block(s) depends (e.g., is based on) on the number of optical ports in the I/O ports 1924.

As discussed above, optical I/Os 1908, which may also be referred to as optical connectors, are placed at the front panel 1904. As mentioned above, connectivity between the MCM assembly 1912 and optical I/Os 1908 may be transferred to the front panel 1904 through optical fibers. This connection may be made directly with an optical I/O 1924 of the switching circuitry or may be made with one or more of the satellite chips 1920. The connection is often made with one or more of the satellite chips 1920 because the satellite chips 1920 may include the electro-optic converters and, possibly, the serializer/deserializer (SERDES) to natively support the connection. The satellite chips 1920 may include one or more of aDSP processor, driver, trans-impedance amplifier, laser, modulator, photodiode, serializer-deserializer, or the like.

Some embodiments of the present disclosure are directed to a multi-chip module (MCM) with a centrally positioned main die and a plurality of peripherally positioned MCM sockets configured to mechanically receive and electrically connect mezzanine packages, which may include co-packaged optics (CPO) packages and co-packaged copper (CPC) packages. Each mezzanine package may include a package substrate including a connector portion that is configured to engage the MCM socket and a main portion extending beyond the periphery of the MCM substrate. The main portion of the mezzanine package may be configured to receive optical devices and/or integrated circuits, such as via mezzanine sockets, to allow connections to be made between the optical devices and/or integrated circuits/RF copper cable connectors and the main die of the MCM. Due to the extension of the mezzanine package beyond the periphery of the MCM substrate, the physical size of the MCM substrate may remain small to reduce cost and avoid the previously discussed production challenges, while allowing connections to a number of optical devices and integrated circuits via the mezzanine packages, which occupy the relatively inexpensive space around the periphery of the MCM substrate. As used herein, the terms “co-packaged optic” (or “CPO”) and “co-packaged copper” (or “CPC”) may refer to an advanced heterogeneous integration of either optics and silicon or copper and silicon, in which either integration may be implemented on a single packaged substrate. The CPO may utilize pluggable optical modules that include an optical engine (OE) to convert optical signals to electrical signals and electrical signals to optical signals. The CPO may further be comprised of an optical component on a photonics die and an electrical component on an electrical die.

As used herein, a ball grid array (BGA) may be a type of surface-mount packaging used for integrated circuits. BGA packages use an array of metallic conductor balls arranged in a grid to permanently mount devices such as microprocessors on a PCB. The metallic conductor balls may then undergo the reflow process described above, wherein the metallic conductor balls may be preheated, then melted to bond the IC to a substrate to form an IC package.

As used herein, the term “flip-chip (FC)” may refer to a method for interconnecting dies, such as semiconductor devices, IC chips, integrated passive devices, and microelectromechanical systems (MEMS), to external circuitry with solder bumps that have been deposited onto chip pads. The solder bumps may be deposited onto chip pads on the top side of the wafer during final wafer processing. The chip may be mounted to external circuitry (such as a circuit board or another chip or wafer) by “flipping” the chip, such that the chip's top side faces down and is positioned to allow the pads of the chip to align with matching pads on the external circuit. Solder is reflowed to complete the interconnect.

### Conclusion

Many modifications and other embodiments will come to mind to one skilled in the art to which this disclosure pertains having the benefit of the teachings presented in the foregoing descriptions and the associated drawings. Therefore, it is to be understood that the disclosure is not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. An electro-absorption modulated laser (EML) comprising:
an optical gain section comprising a gain section number of quantum well layers; and
an absorption section comprising an absorption section number of quantum well layers, wherein the absorption section number of quantum well layers is larger than the gain section number of quantum well layers,
wherein a laser cavity comprising the optical gain section is defined, in part, by a first Bragg grating disposed between the optical gain section and the absorption section.

2. The EML of claim 1, wherein the optical gain section is shorter than 100 um, and the first Bragg grating located between the optical gain section and the absorption section has a peak reflectivity of at least 35%.

3. The EML of claim 1, further comprising a second Bragg grating disposed longitudinally on an opposite side of the optical gain section of the first Bragg grating, wherein the first Bragg grating and the second Bragg grating longitudinally define the laser cavity.

4. The EML of claim 3, wherein the first Bragg grating defines a first stop band, and the second Bragg grating defines a second stop band, and the first stop band and the second stop band are offset from one another by a fraction of respective widths of the first stop band and the second stop band.

5. The EML of claim 4, wherein an overlap in the first stop band and the second stop band defines a wavelength overlap region and a width of the wavelength overlap region is smaller than the respective widths of the first stop band and the second stop band and the width of the wavelength overlap region is smaller or comparable to a mode spacing of the laser cavity, to cause a laser of the EML to operate in a single longitudinal optical mode.

6. The EML of claim 1, further comprising at least one of:
a gain section distributed feedback Bragg grating disposed within the optical gain section and having a smaller coupling coefficient than the first Bragg grating, or
one or more laterally coupled distributed feedback Bragg gratings that are each disposed laterally on one or more sides of the optical gain section and are each optically coupled to an optical mode propagating in the optical gain section.

7. The EML of claim 6, wherein the at least one of the gain section distributed feedback Bragg grating or the one or more laterally coupled distributed feedback Bragg gratings comprise a ¼ wavelength phase shift configured to cause a laser of the EML to operate in a single longitudinal mode.

8. The EML of claim 1, further comprising a mirror, wherein the laser cavity is longitudinally defined by the mirror and the first Bragg grating, the mirror being disposed on a longitudinally opposite end of the optical gain section with respect to the first Bragg grating, and the mirror is a cleaved mirror with a high reflectivity coating.

9. The EML of claim 8, further comprising at least one of:
a gain section distributed feedback Bragg grating disposed within the optical gain section and having a smaller coupling coefficient than the first Bragg grating, or
one or more laterally coupled distributed feedback Bragg gratings that are each disposed laterally on one or more sides of the optical gain section and are each optically coupled to an optical mode propagating in the optical gain section.

10. The EML of claim 9, wherein the at least one of the gain section distributed feedback Bragg grating or the one or more laterally coupled distributed feedback Bragg gratings comprise a ¼ wavelength phase shift configured to cause a laser of the EML to operate in a single longitudinal mode.

11. The EML of claim 9, wherein the at least one of the gain section distributed feedback Bragg grating or the one or more laterally coupled distributed feedback Bragg gratings defines a feedback stop band, the first Bragg grating defines a first stop band and the first stop band and the feedback stop band are offset from one another by a fraction of respective widths of the first stop band and the feedback stop band, an overlap in the first stop band and the feedback stop band defines a wavelength overlap region and a width of the wavelength overlap region is smaller than the respective widths of the first stop band and the feedback stop band and the width of the wavelength overlap region is smaller or comparable to a mode spacing of the laser cavity, to cause a laser of the EML to operate in a single longitudinal optical mode.

12. The EML of claim 1, wherein the absorption section is longitudinally divided into several absorption segments separated by passive optical waveguide segments to form a travelling wave electro-absorption modulator.

13. The EML of claim 1, wherein the travelling wave electro-absorption modulator is configured to be driven by a differential electrical RF signal.

14. The EML of claim 1, further comprising an integrated resistive heater disposed proximate the absorption section, wherein the integrated resistive heater is in thermal communication with the quantum well layers of the absorption section.

15. The EML of claim 14, wherein the integrated resistive heater is operable to maintain the quantum well layers of the absorption section at a substantially constant temperature corresponding to the maximum ambient temperature value when an ambient temperature of an environment about the EML falls below the maximum temperature value.

16. The EML of claim 14, wherein the EML is formed on a chip and the chip is configured to be flip-chip bonded to a silicon photonic chip via laser bonding pads, modulator bonding pads, and heater bonding pads of the silicon photonic chip and laser pads, modulator pads, and heater pads of the chip on which EML is formed, wherein the laser pads and laser bonding pads are configured to create a high thermal conductivity path from the optical gain section of the EML to a silicon photonic substrate heat sink of the silicon photonic chip, and the modulator bonding pads and the heater bonding pads are configured to create a low thermal conductivity path from the integrated resistive heater and the absorption section of the EML to the silicon photonic substrate heat sink.

17. A chip comprising:
a substrate; and
an array of electro-absorption modulated lasers (EMLs) disposed on the substrate, wherein each EML of the array of EMLs comprises:
an optical gain section comprising a gain section number of quantum well layers; and
an absorption section comprising an absorption section number of quantum well layers, wherein the absorption section number of quantum well layers is larger than the gain section number of quantum well layers,
wherein a laser cavity comprising the optical gain section is defined, in part, by a first Bragg grating disposed between the optical gain section and the absorption section.

18. The chip of claim 17, wherein the chip is flip-chip bonded to a silicon photonics carrier.

19. The chip of claim 18, wherein the array of EMLs is a coarse wavelength division multiplexing (CWDM) array and a respective emission wavelength of each EML of the array of EMLs is controlled by a period of the respective first Bragg grating of the EML.

20. A coarse wavelength division multiplexing (CWDM) array chip comprising:
a CWDM source chip comprising:
a substrate; and
an array of electro-absorption modulated lasers (EMLs) disposed on the substrate, wherein each EML of the array of EMLs comprises:
an optical gain section comprising a gain section number of quantum well layers; and
an absorption section comprising an absorption section number of quantum well layers, wherein the absorption section number of quantum well layers is larger than the gain section number of quantum well layers,
wherein a laser cavity comprising the optical gain section is defined, in part, by a first Bragg grating disposed between the optical gain section and the absorption section; and
a silicon photonics carrier,
wherein the CWDM source chip is flip-chip bonded to the silicon photonics carrier,
wherein the array of EMLs is a coarse wavelength division multiplexing (CWDM) array and a respective emission wavelength of each EML of the array of EMLs is controlled by a period of the respective first Bragg grating of the EML, and
wherein the silicon photonics carrier comprises an array waveguide grating (AWG) combiner which combines optical signals generated by respective EMLs of the array of EMLs into a single optical output.
